(19) United States
(12) Patent Application Publication
(10) Pub. No.: US 2026/0282823 A1
(43) Pub. Date: Sep. 17, 2026

(54) AUTOMATED MATERIAL HANDLING SYSTEM

(71) Applicant: Taiwan Semiconductor Manufacturing Company Limited, Hsin-Chu (TW)

(72) Inventors: Yi Chiuan XU, New Taipei City (TW); Lu CHEN-HSIANG, Hsin-Chu City (TW); Che-Cheng CHANG, New Taipei City (TW); Chien Chih LIN, Tainan City (TW)

(21) Appl. No.: 19/076,120

(22) Filed: Mar. 11, 2025

(51) Int. Cl. H01L 21/677

(52) U.S. Cl. CPC H10P 72/3406; H10P 72/3306

(57) ABSTRACT

A door control apparatus includes a door control valve coupled to a door fitted to an opening. The door is configured to transition between a closed position in which the door covers the opening and an open position in which the door does not cover the opening. The door control apparatus includes a first pressure control module coupled to a fluid inlet port defined by the door control valve. The door control apparatus includes a second pressure control module coupled to a fluid outlet port defined by the door control valve. During a door close operation to move the door from the open position to the closed position, the door control apparatus is configured to regulate an inlet pressure associated with the door control valve using the first pressure control module, and regulate a back pressure associated with the door control valve using the second pressure control module.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram schematically depicting a door control apparatus configured to control a door, in accordance with some embodiments.

FIG. 2A illustrates a side view of a door in a scenario in which a door close operation is performed to move the door from an open position to a closed position, an exhaust port, and a first pedestal base, in accordance with some embodiments.

FIG. 2B illustrates a side view of a door in a scenario in which a door close operation is performed to move the door from an open position to a closed position, an exhaust port, and a first pedestal base, in accordance with some embodiments.

FIG. 2C illustrates a side view of a door in a scenario in which a door close operation is performed to move the door from an open position to a closed position, an exhaust port, and a first pedestal base, in accordance with some embodiments.

FIG. 3A illustrates a pressure data structure associated with a door close operation, in accordance with some embodiments.

FIG. 3B illustrates a closing acceleration data structure associated with a door close operation, in accordance with some embodiments.

FIG. 4 illustrates an automated material handling system, in accordance with some embodiments.

FIG. 5A illustrates a perspective view from inside a vacuum transfer chamber defined by a vacuum transfer module, in accordance with some embodiments.

FIG. 5B illustrates a perspective view from inside a vacuum transfer chamber defined by a vacuum transfer module, in accordance with some embodiments.

FIG. 6 is a flow diagram illustrating a method, in accordance with some embodiments.

FIG. 7 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

An automated material handling system has a door fitted to an opening to a chamber and a door control valve to control the door. The door is configured to transition between a closed position in which the door covers the opening to inhibit access to the chamber and an open position in which the door does not cover the opening. A door close operation is performed using the door control valve to move the door from the open position to the closed position.

In accordance with some embodiments, a door close apparatus has a first pressure control module coupled to a fluid inlet port defined by the door control valve and a second pressure control module coupled to a fluid outlet port defined by the door control valve. During the door close operation to move the door from the open position to the closed position, the door control apparatus is configured to regulate an inlet pressure associated with the door control valve using the first pressure control module and regulate a back pressure associated with the door control valve using the second pressure control module. In comparison with merely regulating the inlet pressure associated with the door control valve, using the second pressure control module to regulate the back pressure associated with the door control valve provides for at least one of improved control over operation of the door control valve, improved control over movement of the door, or an improved lifespan of at least one of the door, the wall, the sealing component, etc. In comparison with an implementation in which merely the inlet pressure associated with the door control valve is regulated and the door close operation is slowed down to be completed over a longer duration of time, using the second pressure control module to regulate the back pressure associated with the door control valve provides for faster closing speed of the door such that the door close operation is completed over a duration of time (e.g., about 1 second) that is shorter (e.g., about three times shorter) than the longer duration of time, thereby providing for improved semiconductor production throughput associated with the automated material handling system.

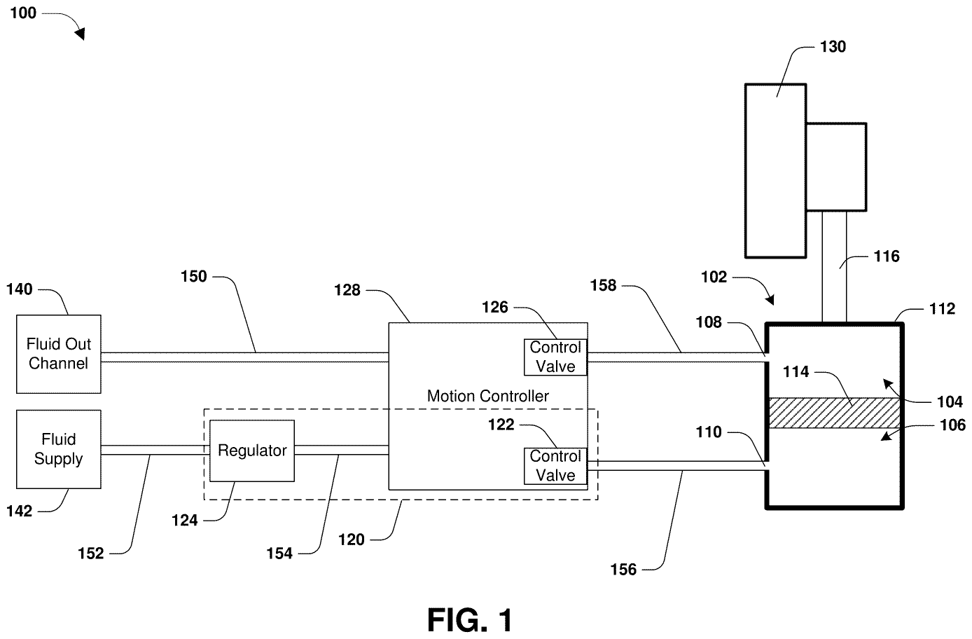

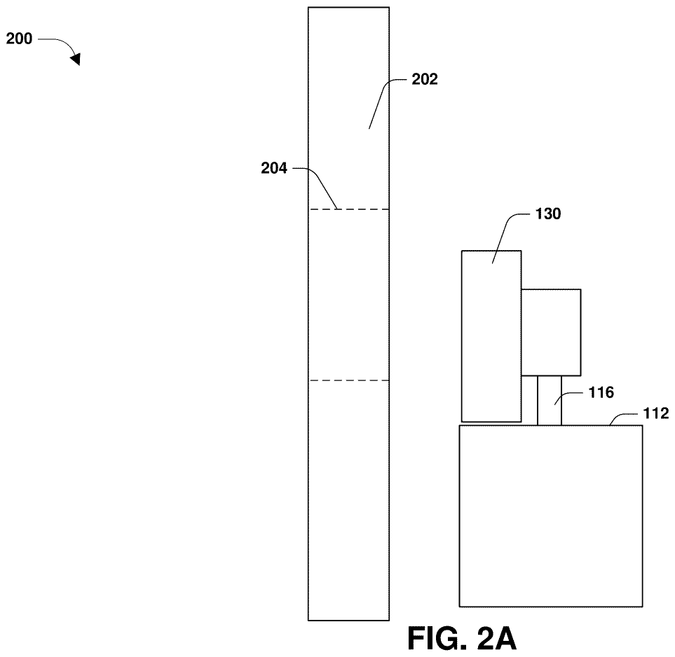

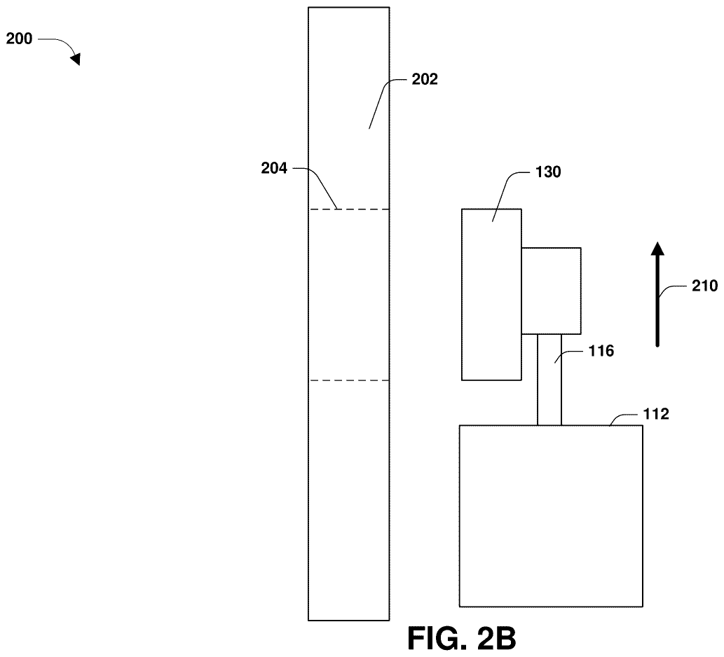

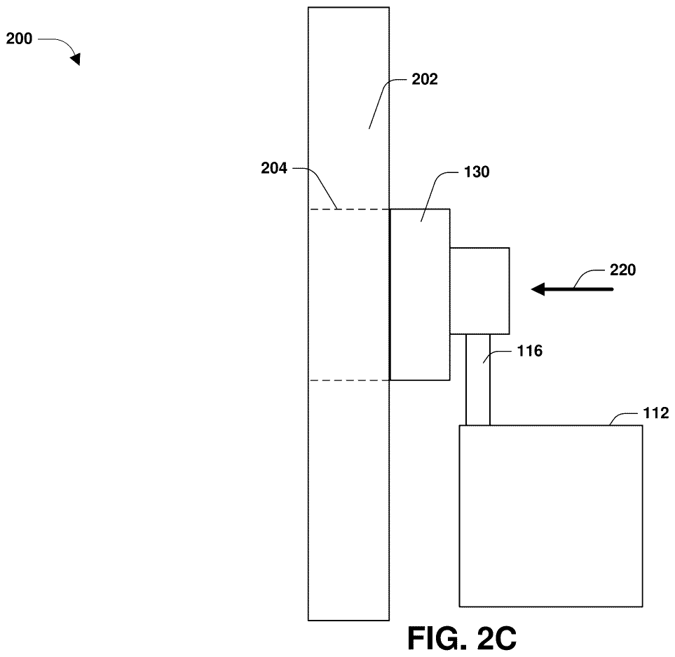

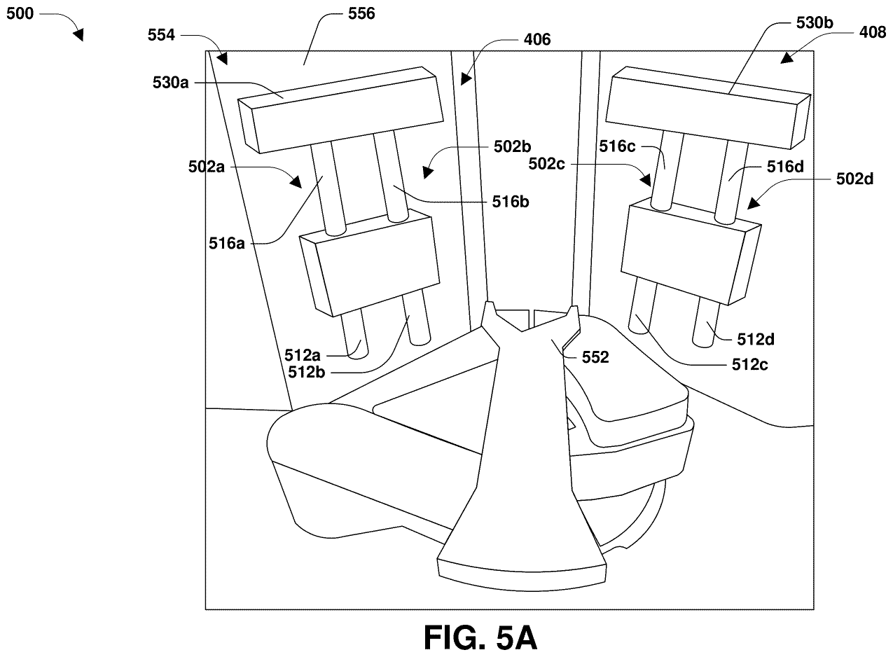

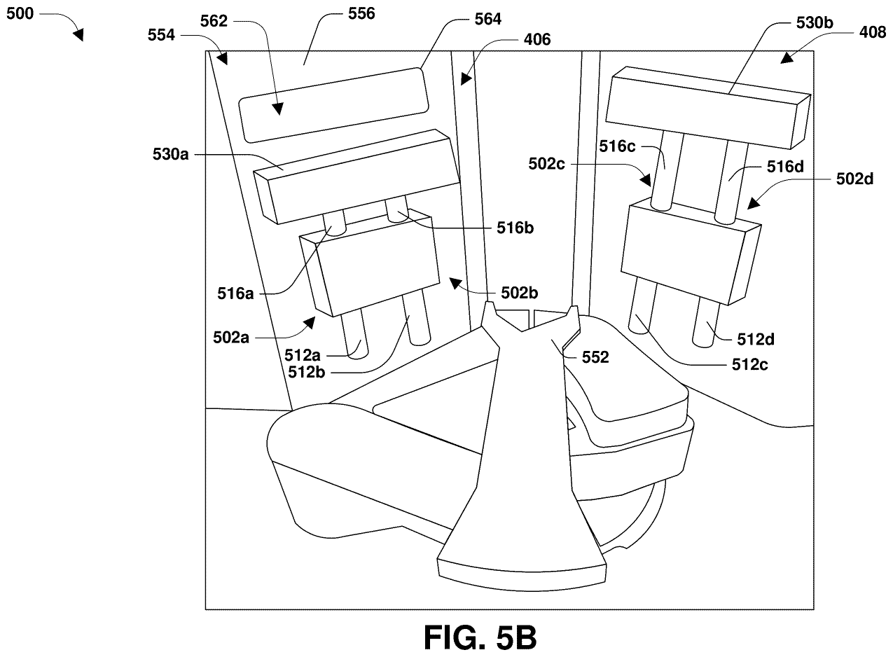

FIG. 1 illustrates a block diagram schematically depicting a door control apparatus 100 configured to control a door 130, in accordance with some embodiments. In some embodiments, the door 130 is fitted to an opening 204 (shown in FIGS. 2A-2C and FIG. 5) to a chamber. In some embodiments, the door control apparatus 100 is configured to move the door 130 between an open position and a closed position. In some embodiments, when the door 130 is in the closed position, the door 130 covers the opening 204 to inhibit access to the chamber. FIG. 2C depicts an example of the door 130 in the closed position relative to the opening 204. In some embodiments, when the door 130 is in the open position, the door 130 does not cover the opening 204. FIG. 2A depicts an example of the door 130 in the open position relative to the opening 204. In some embodiments, the door control apparatus 100 comprises at least one of (i) a door control valve 102 (e.g., a gate valve) coupled to the door 130, (ii) a first pressure control module 120 coupled to a fluid inlet port 110 defined by the door control valve 102, or (iii) a second pressure control module 126 coupled to a fluid outlet port 108 defined by the door control valve 102.

In some embodiments, the door control apparatus 100 is coupled to a fluid supply 142. In some embodiments, the door control apparatus 100 delivers a fluid from the fluid supply 142 to the door control valve 102 to operate the door control valve 102. In some embodiments, the fluid comprises one or more gases comprising at least one of air, compressed air, clean dry air (CDA), compressed CDA, etc. Embodiments are contemplated in which the fluid comprises at least one of liquid, plasma, oil, etc.

In some embodiments, the first pressure control module 120 comprises at least one of a pressure regulator 124 or a first control valve 122. In some embodiments, the pressure regulator 124 is coupled to the fluid supply 142 via a conduit 152. In some embodiments, the pressure regulator 124 is coupled to the first control valve 122 (and/or coupled to a motion controller 128 (e.g., a motion terminal) comprising the first control valve 122) via a conduit 154. In some embodiments, the pressure regulator 124 is configured to supply fluid from the fluid supply 142 to the first control valve 122 using at least one of the conduit 152 or the conduit 154. In some embodiments, the pressure regulator 124 is configured to regulate a pressure of the supplied fluid to the first control valve 122.

In some embodiments, the first control valve 122 is coupled to the fluid inlet port 110 defined by the door control valve 102 via a conduit 156. In some embodiments, the first pressure control module 120 is configured to regulate an inlet pressure associated with the door control valve 102. In some embodiments, the first pressure control module 120 regulates the inlet pressure associated with the door control valve 102 by using the first control valve 122 to control flow of the supplied fluid from the pressure regulator 124 to the fluid inlet port 110 (via the conduit 156, for example). In some embodiments, the first control valve 122 comprises at least one of a solenoid valve or other type of valve.

In some embodiments, the second pressure control module 126 comprises a second control valve. In some embodiments, the second control valve comprises at least one of a solenoid valve or other type of valve. In some embodiments, the second pressure control module 126 (e.g., the second control valve) is coupled to the fluid outlet port 108 defined by the door control valve 102 via a conduit 158. In some embodiments, the second pressure control module 126 is configured to regulate a back pressure associated with the door control valve 102. In some embodiments, the second pressure control module 126 regulates the back pressure associated with the door control valve 102 by using the second pressure control module 126 (e.g., the second control valve) to control flow of fluid to or from the door control valve 102 (via the conduit 158, for example). In some embodiments, the second pressure control module 126 (and/or the motion controller 128 comprising the second pressure control module 126) is coupled to a fluid out channel 140 (e.g., air out channel) via a conduit 150. In some embodiments, the second pressure control module 126 regulates the back pressure by controlling flow of fluid between the fluid outlet port 108 and the fluid out channel 140.

In some embodiments, the second pressure control module 126 (and/or the motion controller 128 comprising the second pressure control module 126) is coupled to a second fluid supply (not shown). The second fluid supply is the same as the fluid supply 142 or different than the fluid supply 142. In some embodiments, the second pressure control module 126 is configured to supply fluid from the second fluid supply to the door control valve 102 using at least one of the conduit 152 or the conduit 154. In some embodiments, the second pressure control module 126 regulates the back pressure associated with the door control valve 102 by at least one of (i) controlling flow of fluid from the second fluid supply to the fluid outlet port 108, or (ii) controlling flow of fluid from the fluid outlet port 108 to the fluid out channel 140.

In some embodiments, the door control valve 102 comprises at least one of a cylinder 112 or a piston 114. In some embodiments, the piston 114 separates a first space 106 in the cylinder 112 from a second space 104 in the cylinder 112. In some embodiments, the first pressure control module 120 is coupled to the first space 106 via the fluid inlet port 110. In some embodiments, the inlet pressure regulated by the first pressure control module 120 corresponds to a first pressure (e.g., air pressure) of the first space 106. In some embodiments, the second pressure control module 126 is coupled to the second space 104 via the fluid outlet port 108. In some embodiments, the back pressure regulated by the second pressure control module 126 corresponds to a second pressure (e.g., air pressure) of the second space 104.

In some embodiments, the door control apparatus 100 performs a door close operation to move the door 130 from the open position to the closed position. In some embodiments, the door control apparatus 100 performs the door close operation by at least one of (i) using the first pressure control module 120 to adjust the inlet pressure associated with the door control valve 102, or (ii) using the second pressure control module 126 to adjust the back pressure associated with the door control valve 102. In some embodiments, at least one of the adjustment of the inlet pressure using the first pressure control module 120 or the adjustment of the back pressure using the second pressure control module 126 causes the piston 114 to move along a first predefined piston path. In some embodiments, the door control valve 102 comprises a shaft 116 coupled to the piston 114 and the door 130. In some embodiments, the movement of the piston 114 along the first predefined piston path causes the door 130 to move along a first predefined door path from the open position to the closed position, such as due, at least in part, to the door 130 being coupled to the piston 114 via the shaft 116.

In some embodiments, the door control apparatus 100 performs the door close operation based upon a pressure profile. In some embodiments, the pressure profile is stored in a memory of the motion controller 128. In some embodiments, the pressure profile is indicative of (i) target inlet pressure values of the inlet pressure associated with the door control valve 102, or (ii) target back pressure values of the back pressure associated with the door control valve 102. In some embodiments, at least one of the first pressure control module 120 or the second pressure control module 126 operates to set the inlet pressure associated with the door control valve 102 to be about equal to a target inlet pressure value indicated by the pressure profile. In some embodiments, at least one of the first pressure control module 120 or the second pressure control module 126 operates to set the back pressure associated with the door control valve 102 to be about equal to a back inlet pressure value indicated by the pressure profile.

FIGS. 2A-2C illustrate side views of the door 130 in a scenario 200 in which the door close operation is performed to move the door 130 from the open position to the closed position, in accordance with some embodiments. In the side views of FIGS. 2A-2C, the opening 204 is covered by a portion of the wall 202. Each of FIGS. 2A-2C provides a pair of dashed-lines denoting a position of the opening 204 behind the portion of the wall 202. Embodiments are contemplated in which a representation of a third opening 562 depicted in FIG. 5B corresponds to a front view representation of the opening 204. Embodiments are contemplated in which representations of a third door 530a depicted in FIGS. 5A-5B correspond to front view representations of the door 130. FIG. 2A illustrates the door 130 in the open position relative to the opening 204, in accordance with some embodiments. In some embodiments, the opening 204 is defined by a wall 202. FIG. 2B illustrates the door 130 at a first point along the first predefined door path while moving from the open position to the closed position. FIG. 2C illustrates the door 130 reaching the closed position to cover the opening 204, in accordance with some embodiments.

In some embodiments, the door close operation includes changing a direction of movement of the door 130 during transition from the open position to the closed position. In some embodiments, during a first part of the door close operation, the door 130 is moved in a first direction 210 (shown in FIG. 2B). In some embodiments, during a second part of the door close operation, the door 130 is moved in a second direction 220 (shown in FIG. 2C) different than the first direction 210. In some embodiments, the changing direction of movement of the door 130 is due, at least in part, to a shape of a channel defined by the door control valve 102 to guide at least one of the piston 114 or the shaft 116. In some embodiments, at least a portion of the channel is curved to cause at least one of the piston 114 or the shaft 116 to change direction to cause the changing direction of the movement of the door 130 during the transition of the door 130 from the open position to the closed position.

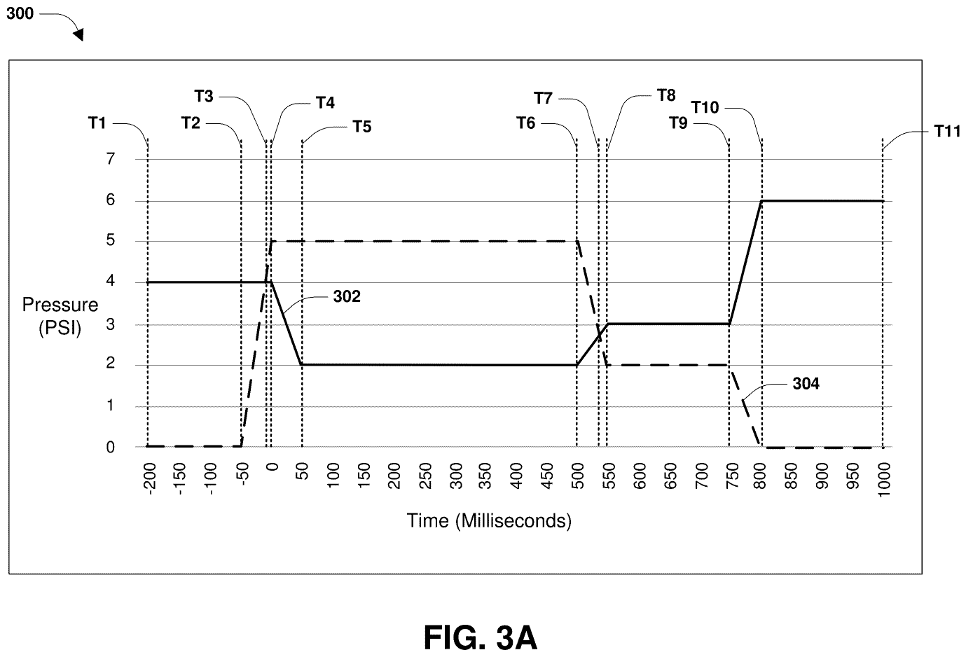

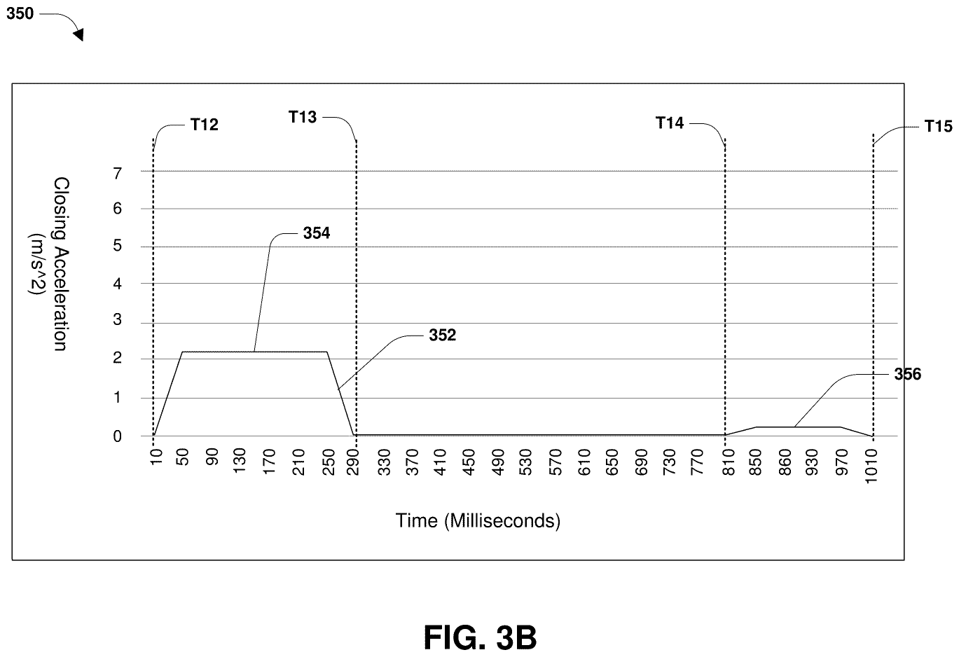

FIG. 3A illustrates a pressure data structure 300 associated with the door close operation, in accordance with some embodiments. The pressure data structure 300 comprises an inlet pressure curve 302 and a back pressure curve 304. In some embodiments, the inlet pressure curve 302 is indicative of values of the inlet pressure associated with the door control valve 102 during a period of time during which the door close operation is performed. In some embodiments, the inlet pressure curve 302 is indicative of target inlet pressure values indicated by the pressure profile. In some embodiments, the back pressure curve 304 is indicative of values of the back pressure associated with the door control valve 102 during the period of time. In some embodiments, the back pressure curve 304 is indicative of target back pressure values indicated by the pressure profile. In accordance with some embodiments, the period of time has a duration of about 1,200 milliseconds spanning from time T1 (e.g., −200 milliseconds) to time T11 (e.g., 1,000 milliseconds).

In some embodiments, between the time T1 and time T4, the inlet pressure is regulated to be about 4 pounds per square inch (PSI). In some embodiments, between time T2 and the time T4, the back pressure is increased from about 0 PSI to about 5 PSI. In some embodiments, between the time T4 and time T5, the inlet pressure is reduced from about 4 PSI to about 2 PSI. In some embodiments, between the time T4 and time T6, the back pressure is regulated to be about 5 PSI. In some embodiments, between the time T5 and the time T6, the inlet pressure is regulated to be about 5 PSI. In some embodiments, between the time T6 and time T8, at least one of (i) the back pressure is reduced from about 5 PSI to about 2 PSI, or (ii) the inlet pressure is increased from about 2 PSI to about 3 PSI. In some embodiments, between the time T8 and time T9, at least one of (i) the back pressure is regulated to be about 2 PSI, or (ii) the inlet pressure is regulated to be about 3 PSI. In some embodiments, between the time T9 and time T10, at least one of (i) the back pressure is reduced from about 2 PSI to about 0 PSI, or (ii) the inlet pressure is increased from about 3 PSI to about 6 PSI. In some embodiments, between the time T10 and the time T11, at least one of (i) the back pressure is regulated to be about 0 PSI, or (ii) the inlet pressure is regulated to be about 6 PSI.

In some embodiments, the inlet pressure is increased (e.g., between the time T6 and time T8 and/or between the time T9 and time T10) by at least one of (i) using the first pressure control module 120 to conduct fluid from the fluid supply 142 to the first space 106 via the fluid inlet port 110, or (ii) using the first pressure control module 120 to increase a flow rate with which fluid is conducted from the fluid supply 142 to the first space 106 via the fluid inlet port 110. In some embodiments, the inlet pressure is regulated to maintain about a target inlet pressure (e.g., between the time T1 and the time T4, between the time T5 and the time T6, between the time T8 and the time T9, and/or between the time T10 and the time T11) by at least one of (i) using the first pressure control module 120 to conduct fluid from the fluid supply 142 to the first space 106 via the fluid inlet port 110, (ii) using the first pressure control module 120 to maintain or reduce a flow rate with which fluid is conducted from the fluid supply 142 to the first space 106 via the fluid inlet port 110, or (iii) using the first pressure control module 120 to mitigate (e.g., at least one of restrict, block, etc.) flow of fluid to or from the first space 106 via the fluid inlet port 110. In some embodiments, the inlet pressure is reduced (e.g., between the time T4 and the time T5) by at least one of (i) using the first pressure control module 120 to reduce a flow rate with which fluid is conducted from the fluid supply 142 to the first space 106 via the fluid inlet port 110, or (ii) using the first pressure control module 120 to mitigate (e.g., at least one of restrict, block, etc.) flow of fluid to the first space 106 via the fluid inlet port 110.

In some embodiments, the back pressure is increased (e.g., between the time T2 and the time T4) by at least one of (i) using the second pressure control module 126 to mitigate (e.g., at least one of restrict, block, etc.) flow of fluid from the second space 104 to the fluid out channel 140, (ii) using the second pressure control module 126 to reduce a flow rate with which fluid is conducted from the second space 104 to the fluid out channel 140, or (iii) using the second pressure control module 126 to conduct fluid from the second fluid supply to the second space 104. In some embodiments, the back pressure is regulated to maintain about a target inlet pressure (e.g., between the time T1 and the time T2, between the time T4 and the time T6, between the time T8 and the time T9, and/or between the time T10 and the time T11) by at least one of (i) using the second pressure control module 126 to mitigate (e.g., at least one of restrict, block, etc.) flow of fluid from the second space 104 to the fluid out channel 140, (ii) using the second pressure control module 126 to reduce a flow rate with which fluid is conducted from the second space 104 to the fluid out channel 140, (iii) using the second pressure control module 126 to conduct fluid from the second fluid supply to the second space 104, or (iv) using the second pressure control module 126 to adjust a flow rate with which fluid is conducted from the second fluid supply to the second space 104. In some embodiments, the back pressure is reduced (e.g., between the time T6 and the time T8, and/or between the time T9 and the time T10) by at least one of (i) using the second pressure control module 126 to conduct fluid from the second space 104 to the fluid out channel 140, (ii) using the second pressure control module 126 to increase a flow rate with which fluid is conducted from the second space 104 to the fluid out channel 140.

The pressure data structure 300 indicates that the back pressure is different than the inlet pressure during at least some of the door close operation, in accordance with some embodiments. In some embodiments, at least one of (i) the inlet pressure is greater than the back pressure between the time T1 and time T3, (ii) the inlet pressure is less than the back pressure between the time T3 and time T7, or (iii) the inlet pressure is greater than the back pressure between the time T7 and the time T11.

In some embodiments, a first fluid that is at least one of stored in the fluid supply 142 or conducted into the first space 106 is the same as or different than a second fluid that is at least one of stored in the second fluid supply or conducted into and/or out of the second space 104. In some embodiments the first fluid comprises at least one of one or more gases (e.g., at least one of air, compressed air, CDA, compressed CDA, etc.), liquid, plasma, oil, etc. In some embodiments the second fluid comprises at least one of one or more gases (e.g., at least one of air, compressed air, CDA, compressed CDA, etc.), liquid, plasma, oil, etc.

In some embodiments, regulating the back pressure using the second pressure control module 126 causes deceleration of at least one of the door control valve 102 or the door 130 during the door close operation. In some embodiments, in comparison with merely regulating the inlet pressure associated with the door control valve 102 without regulating the back pressure associated with the door control valve 102, regulating the back pressure associated with the door control valve 102 provides for at least one of (i) improved control over operating speed and/or acceleration associated with the door control valve 102, (ii) improved control over closing speed and/or acceleration associated with the door 130 (e.g., a speed and/or acceleration with which the door 130 moves during the door close operation), (iii) improved control over a valve closing force associated with the door control valve 102, or (iv) improved control over a door closing force associated with the door 130. In some embodiments, in comparison with merely regulating the inlet pressure associated with the door control valve 102 without regulating the back pressure associated with the door control valve 102, regulating the back pressure associated with the door control valve 102 provides for at least one of (i) a reduction of the operating speed and/or acceleration associated with the door control valve 102 during the door close operation, thereby providing for an improved lifespan of the door control valve 102, (ii) a reduction of the closing speed and/or acceleration associated with the door 130 during the door close operation, thereby providing for at least one of an improved lifespan of the door 130 or an improved lifespan of a sealing component (not shown) (e.g., at least one of an o-ring, a gasket, a rubber seal, etc.) between the door 130 and the wall 202, (iii) a reduction of the valve closing force associated with door control valve 102, thereby providing for an improved lifespan of the door control valve 102, or (iv) a reduction of the door closing force associated with door 130, thereby providing for at least one of an improved lifespan of the door 130, or an improved lifespan of the sealing component between the door 130 and the wall 202.

FIG. 3B illustrates a closing acceleration data structure 350 associated with the door close operation, in accordance with some embodiments. The closing acceleration data structure 350 comprises a closing acceleration curve 352 indicative of a closing acceleration associated with the door 130 during a period of time during which the door close operation is performed, in accordance with some embodiments. In accordance with some embodiments, the period of time has a duration of about 1,000 milliseconds spanning from time T12 (e.g., 10 milliseconds) to time T15 (e.g., 1,010 milliseconds). In some embodiments, the time T12 (e.g., 10 milliseconds) is about 10 milliseconds after the time T4 (e.g., 0 milliseconds) corresponding to the pressure data structure 300. In some embodiments, the time T15 (e.g., 1,010 milliseconds) is about 10 milliseconds after the time T11 (e.g., 1,000 milliseconds) corresponding to the pressure data structure 300.

In some embodiments, the closing acceleration is at least one of equal to or based upon an acceleration of the door 130 during the door close operation (e.g., while the door 130 is moving from the open position to the closed position). In some embodiments, the closing acceleration is at least one of equal to or based upon a g-force (e.g., gravitational force equivalent) of the door 130 during the door close operation (e.g., while the door 130 is moving from the open position to the closed position). In some embodiments, the closing acceleration associated with the door 130 changes during the door close operation. In some embodiments, the closing acceleration has a first extremum 354 (e.g., a plateau or a peak) with a first local maximum of about 2.2 meters per second squared between the time T12 and time T13. In some embodiments, the closing acceleration has a second extremum 356 (e.g., a plateau or a peak) with a second local maximum of about 0.2 meters per second squared between time T14 and the time T15. In some embodiments, the closing acceleration is about 0 between the time T13 and the time T14. In some embodiments, the second local maximum is about 94% less than a local maximum of an extremum of a closing acceleration that would be achieved by merely regulating the inlet pressure associated with the door control valve 102 without regulating the back pressure associated with the door control valve 102.

In some embodiments, the door control apparatus 100 comprises a set of sensors (e.g., a set of one or more sensors) associated with the door control valve 102. In some embodiments, the set of sensors comprise one or more fluid flow sensors (e.g., flow meters) configured to determine one or more fluid flow metrics associated with the door control valve 102. In some embodiments, the one or more fluid flow sensors comprise at least one of a sensor in the first space 106 in the cylinder 112, a sensor in the second space 104 in the cylinder 112, a sensor in the conduit 158, a sensor in the conduit 156, one or more sensors of the motion controller 128 (e.g., the one or more sensors may be embedded in and/or built into the motion controller 128), etc. In some embodiments, the one or more fluid flow metrics comprise at least one of (i) a flow rate with which fluid (e.g., compressed air and/or other fluid) is conducted to or from the first space 106 via the fluid inlet port 110, or (ii) a flow rate with which fluid (e.g., compressed air and/or other fluid) is conducted to or from the second space 104 via the fluid outlet port 108. In some embodiments, the motion controller 128 uses the one or more fluid flow metrics as feedback to regulate at least one of the inlet pressure associated with the door control valve 102 using the first pressure control module 120 or the back pressure associated with the door control valve 102 using the second pressure control module 126. In some embodiments, the first pressure control module 120 regulates the back pressure associated with the door control valve 102 based upon the one or more fluid flow metrics. In some embodiments, the first pressure control module 120 adjusts (e.g., increases or reduces) the back pressure associated with the door control valve 102 in response to detecting a change to a metric of the one or more fluid flow metrics. In some embodiments. the second pressure control module 126 regulates the inlet pressure associated with the door control valve 102 based upon the one or more fluid flow metrics. In some embodiments, the second pressure control module 126 adjusts (e.g., increases or reduces) the inlet pressure associated with the door control valve 102 in response to detecting a change to a metric of the one or more fluid flow metrics.

In some embodiments, a computer (e.g., a computer of the motion controller 128 or other computer) is configured to determine a control valve health (e.g., a gate valve health) associated with the door control valve 102 based upon the one or more fluid flow metrics. In some embodiments, the control valve health is indicative of at least one of (i) a predicted lifespan associated with at least one of the door control valve 102 or the cylinder 112 or (ii) a predicted replacement time associated with at least one of the door control valve 102 or the cylinder 112. In some embodiments, at least one of the predicted lifespan or the predicted replacement time is a function of a fluid flow metric of the one or more fluid flow metrics, where an increased value of the fluid flow metric (e.g., an increased flow rate to or from the door control valve 102) results in the predicted lifespan to have a shorter duration or the predicted replacement time to indicate an earlier time. In some embodiments, the computer uses at least one of the predicted lifespan or the predicted replacement time to automatically schedule and trigger a maintenance operation associated with at least one of the door control valve 102 or the cylinder 112. In some embodiments, the maintenance operation comprises allocating one or more resources (e.g., at least one of one or more tools, manpower, replacement items, etc.) to at least one of repair or replace at least one of the door control valve 102 or the cylinder 112. In some embodiments, the control valve health is indicative of a leakage state associated with the door control valve 102. In some embodiments, the leakage state indicates whether the door control valve 102 has a leak. In some embodiments, in response to determining that the door control valve 102 has a leak, the computer schedules and triggers a maintenance operation to address the leak (by at least one of repairing or replacing at least one of the door control valve 102 or the cylinder 112, for example). Thus, in accordance with some embodiments, the computer at least one of automatically (i) predicts one or more lifespans of at least one of one or more door control valves or one or more cylinders of the one or more door control valves or (ii) manages maintenance operations for the one or more door control valves, thereby providing for reduced manual effort and more accurate management of door control valves (e.g., a lifespan of a door control valve or a cylinder is difficult or impossible to predict manually).

In some embodiments, the set of sensors comprise one or more pressure sensors configured to determine one or more pressure metrics associated with the door control valve 102. In some embodiments, the one or more pressure sensors comprise at least one of a sensor in the first space 106 in the cylinder 112, a sensor in the second space 104 in the cylinder 112, a sensor in the conduit 158, a sensor in the conduit 156, one or more sensors of the motion controller 128 (e.g., the one or more sensors may be embedded in and/or built into the motion controller 128), etc. In some embodiments, the one or more pressure metrics comprise at least one of (i) a measured pressure (e.g., air pressure) of the first space 106 or (ii) a measured pressure (e.g., air pressure) of the second space 104.

In some embodiments, the motion controller 128 uses the one or more pressure metrics as feedback to regulate at least one of the inlet pressure associated with the door control valve 102 using the first pressure control module 120 or the back pressure associated with the door control valve 102 using the second pressure control module 126. In some embodiments, the first pressure control module 120 regulates the back pressure associated with the door control valve 102 based upon the one or more pressure metrics. In some embodiments, the first pressure control module 120 operates to increase the back pressure associated with the door control valve 102 in response to determining that the measured pressure of the second space 104 is less than a target back pressure indicated by the pressure profile. In some embodiments, the first pressure control module 120 operates to reduce the back pressure associated with the door control valve 102 in response to determining that the measured pressure of the second space 104 is greater than a target back pressure indicated by the pressure profile.

In some embodiments, the second pressure control module 126 regulates the inlet pressure associated with the door control valve 102 based upon the one or more pressure metrics. In some embodiments, the second pressure control module 126 operates to increase the inlet pressure associated with the door control valve 102 in response to determining that the measured pressure of the first space 106 is less than a target inlet pressure indicated by the pressure profile. In some embodiments, the second pressure control module 126 operates to reduce the inlet pressure associated with the door control valve 102 in response to determining that the measured pressure of the first space 106 is greater than a target inlet pressure indicated by the pressure profile.

In some embodiments, at least one of the motion controller 128, the first pressure control module 120, or the second pressure control module 126 uses the pressure profile and the one or more pressure metrics to determine valve actuation timing associated with controlling the door control valve 102. In some embodiments, the pressure profile comprises a pressure detection data structure comprising predefined pressure thresholds associated with actions and/or timings for valve actuation associated with the door control valve 102. In some embodiments, at least one of the motion controller 128, the first pressure control module 120, or the second pressure control module 126 operates the door control valve 102 based upon a comparison of a pressure metric of the one or more pressure metrics with a predefined pressure threshold of the pressure detection data structure.

In some embodiments, the door control apparatus 100 comprises a failover module (e.g., a bypass valve). In some embodiments, the failover module is coupled to the door control valve 102. In some embodiments, the failover module is configured to take over operation of the door control valve 102 in response to at least one of a failure associated with the motion controller 128, a failure associated with the first pressure control module 120, a failure associated with the second pressure control module 126, a failure associated with the first control valve 122, a failure associated with the second control valve, etc. In some embodiments, the failover module is embedded in and/or built into the motion controller 128.

In some embodiments, the door control apparatus 100 performs a door open operation to move the door 130 from the closed position to the open position. In some embodiments, the door control apparatus 100 performs the door open operation by at least one of (i) using the first pressure control module 120 to adjust the inlet pressure associated with the door control valve 102 or (ii) using the second pressure control module 126 to adjust the back pressure associated with the door control valve 102. In some embodiments, at least one of the adjustment of the inlet pressure using the first pressure control module 120 or the adjustment of the back pressure using the second pressure control module 126 causes the piston 114 to move along a second predefined piston path. In some embodiments, the movement of the piston 114 along the second predefined piston path causes the door 130 to move along a second predefined door path from the closed position to the open position, such as due, at least in part, to the door 130 being coupled to the piston 114 via the shaft 116.

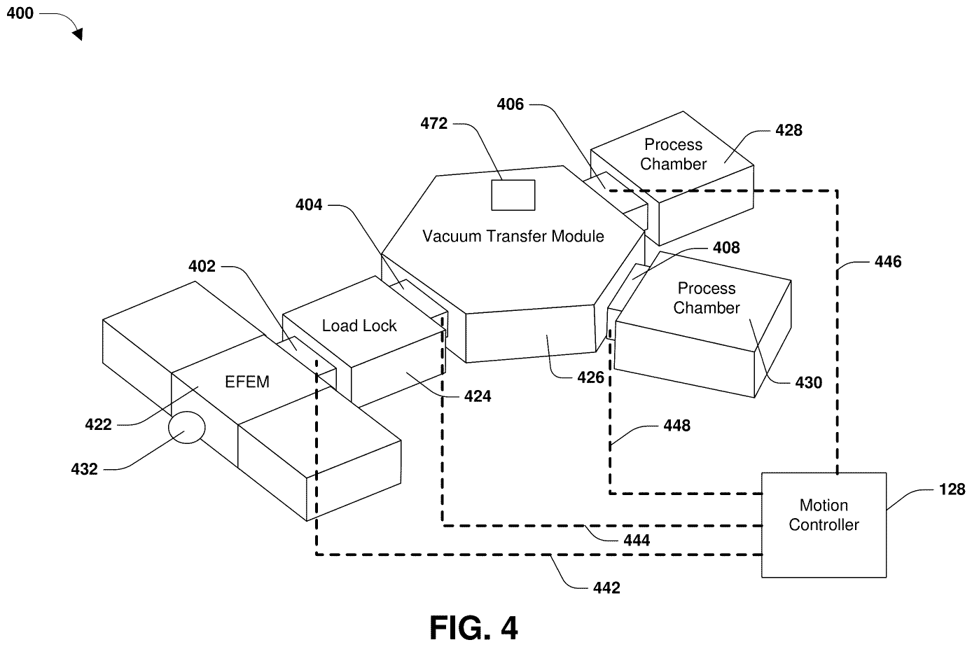

In some embodiments, the door control apparatus 100 is incorporated in an automated material handling system 400 to control some or all doors of the automated material handling system 400. FIG. 4 illustrates a representation of the automated material handling system 400, in accordance with some embodiments. In some embodiments, the automated material handling system 400 comprises at least one of at least one of an Equipment Front End Module (EFEM) 422, a load lock module 424, a vacuum transfer module (VTM) 426, a first wafer processing station 428, or a second wafer processing station 430. In some embodiments, the automated material handling system 400 comprises the door control apparatus 100 to control door assemblies interspersed throughout the automated material handling system 400. In some embodiments, the door assemblies comprise at least one of a first door assembly 402, a second door assembly 404, a third door assembly 406, or a fourth door assembly 408.

In some embodiments, the EFEM 422 is configured to retrieve a first semiconductor wafer 432 from a wafer storage device (not shown). In some embodiments, the wafer storage device comprises at least one of a front opening unified pod (FOUP), a cassette pod, a reticle pod, or other type of wafer storage device. In some embodiments, the wafer storage device is used to store one or more semiconductor wafers comprising the first semiconductor wafer 432. In some embodiments, the one or more semiconductor wafers comprise a batch of semiconductor wafers. In some embodiments, the one or more semiconductor wafers comprise at least one of one or more photomasks, one or more semiconductor devices, one or more dies, etc. In some embodiments, the one or more semiconductor wafers are stacked vertically in the wafer storage device. In some embodiments, the one or more semiconductor wafers are supported by a support frame, of the wafer storage device, having at least one of wafer shelves or wafer slots. In some embodiments, a semiconductor wafer, such as the first semiconductor wafer 432, stored in the wafer storage device comprises one or more layers, such as at least one of a semiconductor layer, a conductor layer, an insulator layer, a substrate, etc.

In some embodiments, the first door assembly 402 comprises at least one of a first door (e.g., the door 130) or a first door control valve (e.g., the door control valve 102) coupled to the first door. In some embodiments, the first door is fitted to a first opening (not shown) to at least one of an EFEM chamber defined by the EFEM 422 or a load lock chamber defined by the load lock module 424. In some embodiments, the door control apparatus 100 is configured to move the first door between a first door open position (e.g., the open position of the door 130 depicted in FIG. 2A) and a first door closed position (e.g., the closed position of the door 130 depicted in FIG. 2C). In some embodiments, when the first door is in the first door open position, the first door covers the first opening to inhibit access to at least one of the EFEM chamber defined by the EFEM 422 or the load lock chamber defined by the load lock module 424. In some embodiments, when the first door is in the first door open position, the first door does not cover the first opening. In some embodiments, the door control apparatus 100 comprises at least one of (i) a third pressure control module (e.g., the first pressure control module 120) coupled to a first fluid inlet port (e.g., the fluid inlet port 110) defined by the first door control valve or (ii) a fourth pressure control module (e.g., the second pressure control module 126) coupled to a first fluid outlet port (e.g., the fluid outlet port 108) defined by the first door control valve.

In some embodiments, the third pressure control module comprises at least one of the pressure regulator 124 or a third control valve (e.g., the first control valve 122). In some embodiments, the pressure regulator 124 is configured to supply fluid from the fluid supply 142 (or a different fluid supply) to the third control valve. In some embodiments, the pressure regulator 124 is configured to regulate a pressure of the supplied fluid to the third control valve. In some embodiments, the third pressure control module is configured to regulate an inlet pressure associated with the first door control valve. In some embodiments, the third pressure control module regulates the inlet pressure associated with the first door control valve by using the third control valve to control flow of the supplied fluid from the pressure regulator 124 to the first fluid inlet port. In some embodiments, the third control valve comprises at least one of a solenoid valve or other type of valve. In some embodiments, the third pressure control module regulates the inlet pressure associated with the first door control valve by using one or more of the techniques provided herein with respect to regulating the inlet pressure associated with the door control valve 102 using the first pressure control module 120.

In some embodiments, the fourth pressure control module comprises a fourth control valve. In some embodiments, the fourth control valve comprises at least one of a solenoid valve or other type of valve. In some embodiments, the fourth pressure control module is configured to regulate a back pressure associated with the first door control valve. In some embodiments, the fourth pressure control module regulates the back pressure associated with the first door control valve by using the fourth pressure control module (e.g., the fourth control valve) to control flow of fluid to or from the first door control valve. In some embodiments, the fourth pressure control module (and/or the motion controller 128 comprising the fourth pressure control module) is coupled to the fluid out channel 140 (e.g., air out channel). In some embodiments, the fourth pressure control module regulates the back pressure associated with the first door control valve by controlling flow of fluid between the first fluid outlet port and the fluid out channel 140. In some embodiments, the fourth pressure control module regulates the back pressure associated with the first door control valve by using one or more of the techniques provided herein with respect to regulating the back pressure associated with the door control valve 102 using the second pressure control module 126.

In some embodiments, the fourth pressure control module (and/or the motion controller 128 comprising the fourth pressure control module) is coupled to the second fluid supply. In some embodiments, the fourth pressure control module is configured to supply fluid from the second fluid supply to the door control valve 102. In some embodiments, the fourth pressure control module regulates the back pressure associated with the first door control valve by at least one of (i) controlling flow of fluid from the second fluid supply to the first fluid outlet port, or (ii) controlling flow of fluid from the first fluid outlet port to the fluid out channel 140.

In some embodiments, the first door control valve comprises at least one of a first cylinder (e.g., the cylinder 112) or a first piston (e.g., the piston 114). In some embodiments, the first piston separates a third space in the first cylinder from a fourth space in the first cylinder. In some embodiments, the third pressure control module is coupled to the third space via the first fluid inlet port. In some embodiments, the inlet pressure associated with the first door control valve corresponds to a third pressure (e.g., air pressure) of the third space. In some embodiments, the fourth pressure control module is coupled to the fourth space via the first fluid outlet port. In some embodiments, the back pressure associated with the first door control valve corresponds to a fourth pressure (e.g., air pressure) of the fourth space.

In some embodiments, the door control apparatus 100 performs a second door open operation to move the first door of the first door assembly 402 from the first door closed position to the first door open position. In some embodiments, the door control apparatus 100 performs the second door open operation by at least one of (i) using the third pressure control module to adjust the inlet pressure associated with the first door control valve, or (ii) using the fourth pressure control module to adjust the back pressure associated with the first door control valve. In some embodiments, the first door control valve of the first door assembly 402 comprises a first shaft (e.g., the shaft 116) coupled to the first piston and the first door. In some embodiments, at least one of the adjustment of the inlet pressure using the third pressure control module or the adjustment of the back pressure using the fourth pressure control module causes the first piston to move along a third predefined piston path. In some embodiments, the movement of the first piston along the third predefined piston path causes the first door of the first door assembly 402 to move along a third predefined door path from the first door closed position to the first door open position, such as due, at least in part, to the first door of the first door assembly 402 being coupled to the first piston via the first shaft.

In some embodiments, in response to performing the second door open operation to move the first door of the first door assembly 402 from the first door closed position to the first door open position, the first door is kept in the first door open position for a first time window to allow a first semiconductor wafer handling device (not shown) to transfer the first semiconductor wafer 432 from the EFEM chamber defined by the EFEM 422 to the load lock chamber defined by the load lock module 424. In some embodiments, the first semiconductor wafer handling device comprises at least one of a robotic arm or other suitable device. In some embodiments, the first semiconductor wafer handling device supports (e.g., at least one of carries, grips, etc.) the first semiconductor wafer 432 and moves the first semiconductor wafer 432 through the first opening from the EFEM chamber defined by the EFEM 422 to the load lock chamber defined by the load lock module 424 while the first door is in the first door open position.

In some embodiments, the door control apparatus 100 performs a second door close operation to move the first door of the first door assembly 402 from the first door open position to the first door closed position. In some embodiments, the door control apparatus 100 performs the second door close operation in response to transferring the first semiconductor wafer 432 through the first opening from the EFEM chamber defined by the EFEM 422 to the load lock chamber defined by the load lock module 424. In some embodiments, the door control apparatus 100 performs the second door close operation by at least one of (i) using the third pressure control module to adjust the inlet pressure associated with the first door control valve or (ii) using the fourth pressure control module to adjust the back pressure associated with the first door control valve. In some embodiments, at least one of the adjustment of the inlet pressure using the third pressure control module or the adjustment of the back pressure using the fourth pressure control module causes the first piston to move along a fourth predefined piston path. In some embodiments, the movement of the first piston along the fourth predefined piston path causes the first door of the first door assembly 402 to move along a fourth predefined door path from the first door open position to the first door closed position, such as due, at least in part, to the first door of the first door assembly 402 being coupled to the first piston via the first shaft.

In some embodiments, the first door control valve comprises one, some, or all of the features, functions, interrelationships with other elements, etc. provided herein with respect to the door control valve 102. In some embodiments, the third pressure control module comprises one, some, or all of the features, functions, interrelationships with other elements, etc. provided herein with respect to the first pressure control module 120. In some embodiments, the fourth pressure control module comprises one, some, or all of the features, functions, interrelationships with other elements, etc. provided herein with respect to the second pressure control module 126. In some embodiments, the first door control valve, the third pressure control module, and/or the fourth pressure control module are used to perform the second door close operation on the first door of the first door assembly 402 using one or more of the techniques provided herein with respect to using the door control valve 102, the first pressure control module 120, and/or the second pressure control module 126 to perform the door close operation on the door 130. In some embodiments, at least one of the back pressure associated with the first door control valve or the inlet pressure associated with the first door control valve is controlled in accordance with the pressure data structure 300 of FIG. 3A to perform the second door close operation. In some embodiments, at least one of the back pressure associated with the first door control valve or the inlet pressure associated with the first door control valve is controlled based upon the pressure profile or a different pressure profile (stored on the motion controller 128, for example) to perform the second door close operation.

In some embodiments, the door control apparatus 100 comprises a second set of sensors (e.g., a set of one or more sensors) associated with the first door control valve of the first door assembly 402. In some embodiments, the second set of sensors comprise one or more fluid flow sensors (e.g., flow meters) configured to determine one or more fluid flow metrics associated with the first door control valve. In some embodiments, the motion controller 128 uses the one or more fluid flow metrics as feedback to regulate at least one of the inlet pressure associated with the first door control valve or the back pressure associated with the first door control valve.

In some embodiments, the computer is configured to determine a second control valve health (e.g., a gate valve health) associated with the first door control valve based upon the one or more fluid flow metrics. In some embodiments, the second control valve health is indicative of at least one of (i) a second predicted lifespan associated with at least one of the first door control valve or the first cylinder or (ii) a second predicted replacement time associated with at least one of the first door control valve or the first cylinder. In some embodiments, the computer uses at least one of the second predicted lifespan or the second predicted replacement time to automatically schedule and trigger a maintenance operation associated with at least one of the first door control valve or the first cylinder. In some embodiments, the maintenance operation comprises allocating one or more resources (e.g., at least one of one or more tools, manpower, replacement items, etc.) to at least one of repair or replace at least one of the first door control valve or the first cylinder.

In some embodiments, the second set of sensors comprise one or more pressure sensors configured to determine one or more pressure metrics associated with the first door control valve. In some embodiments, the motion controller 128 uses the one or more pressure metrics as feedback to regulate at least one of the inlet pressure associated with the first door control valve or the back pressure associated with the first door control valve.

In some embodiments, the second door assembly 404 comprises at least one of a second door (e.g., the door 130) or a second door control valve (e.g., the door control valve 102) coupled to the second door. In some embodiments, the second door is fitted to a second opening (not shown) to at least one of the load lock chamber defined by the load lock module 424 or a vacuum transfer chamber defined by the vacuum transfer module 426. In some embodiments, the door control apparatus 100 is configured to move the second door between a second door open position (e.g., the open position of the door 130 depicted in FIG. 2A) and a second door closed position (e.g., the closed position of the door 130 depicted in FIG. 2C). In some embodiments, when the second door is in the second door open position, the second door covers the second opening to inhibit access to at least one of the load lock chamber defined by the load lock module 424 or the vacuum transfer chamber defined by the vacuum transfer module 426. In some embodiments, when the second door is in the second door open position, the second door does not cover the second opening. In some embodiments, the door control apparatus 100 comprises at least one of (i) a fifth pressure control module (e.g., the first pressure control module 120) coupled to a second fluid inlet port (e.g., the fluid inlet port 110) defined by the second door control valve or (ii) a sixth pressure control module (e.g., the second pressure control module 126) coupled to a second fluid outlet port (e.g., the fluid outlet port 108) defined by the second door control valve.

In some embodiments, the fifth pressure control module comprises at least one of the pressure regulator 124 or a fifth control valve (e.g., the first control valve 122). In some embodiments, the pressure regulator 124 is configured to supply fluid from the fluid supply 142 (or a different fluid supply) to the fifth control valve. In some embodiments, the pressure regulator 124 is configured to regulate a pressure of the supplied fluid to the fifth control valve. In some embodiments, the fifth pressure control module is configured to regulate an inlet pressure associated with the second door control valve. In some embodiments, the fifth pressure control module regulates the inlet pressure associated with the second door control valve by using the fifth control valve to control flow of the supplied fluid from the pressure regulator 124 to the second fluid inlet port. In some embodiments, the fifth control valve comprises at least one of a solenoid valve or other type of valve. In some embodiments, the fifth pressure control module regulates the inlet pressure associated with the second door control valve by using one or more of the techniques provided herein with respect to regulating the inlet pressure associated with the door control valve 102 using the first pressure control module 120.

In some embodiments, the sixth pressure control module comprises a sixth control valve. In some embodiments, the sixth control valve comprises at least one of a solenoid valve or other type of valve. In some embodiments, the sixth pressure control module is configured to regulate a back pressure associated with the second door control valve. In some embodiments, the sixth pressure control module regulates the back pressure associated with the second door control valve by using the sixth pressure control module (e.g., the sixth control valve) to control flow of fluid to or from the second door control valve. In some embodiments, the sixth pressure control module (and/or the motion controller 128 comprising the sixth pressure control module) is coupled to the fluid out channel 140 (e.g., air out channel). In some embodiments, the sixth pressure control module regulates the back pressure associated with the second door control valve by controlling flow of fluid between the second fluid outlet port and the fluid out channel 140. In some embodiments, the sixth pressure control module regulates the back pressure associated with the second door control valve by using one or more of the techniques provided herein with respect to regulating the back pressure associated with the door control valve 102 using the second pressure control module 126.

In some embodiments, the sixth pressure control module (and/or the motion controller 128 comprising the sixth pressure control module) is coupled to the second fluid supply. In some embodiments, the sixth pressure control module is configured to supply fluid from the second fluid supply to the door control valve 102. In some embodiments, the sixth pressure control module regulates the back pressure associated with the second door control valve by at least one of (i) controlling flow of fluid from the second fluid supply to the second fluid outlet port or (ii) controlling flow of fluid from the second fluid outlet port to the fluid out channel 140.

In some embodiments, the second door control valve comprises at least one of a second cylinder (e.g., the cylinder 112) or a second piston (e.g., the piston 114). In some embodiments, the second piston separates a fifth space in the second cylinder from a sixth space in the second cylinder. In some embodiments, the fifth pressure control module is coupled to the fifth space via the second fluid inlet port. In some embodiments, the inlet pressure associated with the second door control valve corresponds to a fifth pressure (e.g., air pressure) of the fifth space. In some embodiments, the sixth pressure control module is coupled to the sixth space via the second fluid outlet port. In some embodiments, the back pressure associated with the second door control valve corresponds to a sixth pressure (e.g., air pressure) of the sixth space.

In some embodiments, the door control apparatus 100 performs a third door open operation to move the second door of the second door assembly 404 from the second door closed position to the second door open position. In some embodiments, the door control apparatus 100 performs the third door open operation by at least one of (i) using the fifth pressure control module to adjust the inlet pressure associated with the second door control valve or (ii) using the sixth pressure control module to adjust the back pressure associated with the second door control valve. In some embodiments, the second door control valve of the second door assembly 404 comprises a second shaft (e.g., the shaft 116) coupled to the second piston and the second door. In some embodiments, at least one of the adjustment of the inlet pressure using the fifth pressure control module or the adjustment of the back pressure using the sixth pressure control module causes the second piston to move along a fifth predefined piston path. In some embodiments, the movement of the second piston along the fifth predefined piston path causes the second door of the second door assembly 404 to move along a fifth predefined door path from the second door closed position to the second door open position, such as due, at least in part, to the second door of the second door assembly 404 being coupled to the second piston via the second shaft.

In some embodiments, in response to performing the third door open operation to move the second door of the second door assembly 404 from the second door closed position to the second door open position, the second door is kept in the second door open position for a second time window to allow a second semiconductor wafer handling device (not shown) to transfer the first semiconductor wafer 432 from the load lock chamber defined by the load lock module 424 to the vacuum transfer chamber defined by the vacuum transfer module 426. In some embodiments, the second semiconductor wafer handling device comprises at least one of a robotic arm or other suitable device. In some embodiments, the second semiconductor wafer handling device supports (e.g., at least one of carries, grips, etc.) the first semiconductor wafer 432 and moves the first semiconductor wafer 432 through the second opening from the load lock chamber defined by the load lock module 424 to the vacuum transfer chamber defined by the vacuum transfer module 426 while the second door is in the second door open position.

In some embodiments, the door control apparatus 100 performs a third door close operation to move the second door of the second door assembly 404 from the second door open position to the second door closed position. In some embodiments, the door control apparatus 100 performs the third door close operation in response to transferring the first semiconductor wafer 432 through the second opening from the load lock chamber defined by the load lock module 424 to the vacuum transfer chamber defined by the vacuum transfer module 426. In some embodiments, the door control apparatus 100 performs the third door close operation by at least one of (i) using the fifth pressure control module to adjust the inlet pressure associated with the second door control valve or (ii) using the sixth pressure control module to adjust the back pressure associated with the second door control valve. In some embodiments, at least one of the adjustment of the inlet pressure using the fifth pressure control module or the adjustment of the back pressure using the sixth pressure control module causes the second piston to move along a sixth predefined piston path. In some embodiments, the movement of the second piston along the sixth predefined piston path causes the second door of the second door assembly 404 to move along a sixth predefined door path from the second door open position to the second door closed position, such as due, at least in part, to the second door of the second door assembly 404 being coupled to the second piston via the second shaft.

In some embodiments, the second door control valve comprises one, some, or all of the features, functions, interrelationships with other elements, etc. provided herein with respect to the door control valve 102. In some embodiments, the fifth pressure control module comprises one, some, or all of the features, functions, interrelationships with other elements, etc. provided herein with respect to the first pressure control module 120. In some embodiments, the sixth pressure control module comprises one, some, or all of the features, functions, interrelationships with other elements, etc. provided herein with respect to the second pressure control module 126. In some embodiments, the second door control valve, the fifth pressure control module, and/or the sixth pressure control module are used to perform the third door close operation on the second door of the second door assembly 404 using one or more of the techniques provided herein with respect to using the door control valve 102, the first pressure control module 120, and/or the second pressure control module 126 to perform the door close operation on the door 130. In some embodiments, at least one of the back pressure associated with the second door control valve or the inlet pressure associated with the second door control valve is controlled in accordance with the pressure data structure 300 of FIG. 3A to perform the third door close operation. In some embodiments, at least one of the back pressure associated with the second door control valve or the inlet pressure associated with the second door control valve is controlled based upon the pressure profile or a different pressure profile (stored on the motion controller 128, for example) to perform the third door close operation.

In some embodiments, the vacuum transfer module 426 comprises a vacuum source 472 configured to adjust a pressure (e.g., air pressure) in the vacuum transfer chamber. In some embodiments, the vacuum source 472 is configured to establish a vacuum (e.g., partial vacuum) in the vacuum transfer chamber. In some embodiments, the vacuum source 472 is configured to reduce the pressure in the vacuum transfer chamber relative to outside the vacuum transfer chamber. In some embodiments, the vacuum source 472 reduces the pressure in the vacuum transfer chamber to a target pressure. In some embodiments, the target pressure is less than at least one of (i) a pressure (e.g., air pressure) in the load lock chamber defined by the load lock module 424, (ii) a pressure (e.g., air pressure) in a first wafer processing chamber defined by the first wafer processing station 428, (iii) a pressure (e.g., air pressure) in a second wafer processing chamber defined by the second wafer processing station 430, or (iv) a pressure (e.g., air pressure) in an external environment (e.g., a semiconductor manufacturing facility) where one or more components of the automated material handling system 400 are located. In some embodiments, the vacuum source 472 is configured to reduce the pressure in the vacuum transfer chamber to the target pressure while the first semiconductor wafer 432 is in the vacuum transfer chamber. In some embodiments, the vacuum source 472 comprises a vacuum pump, such as a turbo pump or any other suitable pump that is operable to reduce the pressure in the vacuum transfer chamber to the target pressure.

In some embodiments, the door control apparatus 100 comprises a third set of sensors (e.g., a set of one or more sensors) associated with the second door control valve of the second door assembly 404. In some embodiments, the third set of sensors comprise one or more fluid flow sensors (e.g., flow meters) configured to determine one or more fluid flow metrics associated with the second door control valve. In some embodiments, the motion controller 128 uses the one or more fluid flow metrics as feedback to regulate at least one of the inlet pressure associated with the second door control valve or the back pressure associated with the second door control valve.

In some embodiments, the computer is configured to determine a third control valve health (e.g., a gate valve health) associated with the second door control valve based upon the one or more fluid flow metrics. In some embodiments, the second control valve health is indicative of at least one of (i) a third predicted lifespan associated with at least one of the second door control valve or the second cylinder, or (ii) a third predicted replacement time associated with at least one of the second door control valve or the second cylinder. In some embodiments, the computer uses at least one of the third predicted lifespan or the third predicted replacement time to automatically schedule and trigger a maintenance operation associated with at least one of the second door control valve or the second cylinder. In some embodiments, the maintenance operation comprises allocating one or more resources (e.g., at least one of one or more tools, manpower, replacement items, etc.) to at least one of repair or replace at least one of the second door control valve or the second cylinder.

In some embodiments, the third set of sensors comprise one or more pressure sensors configured to determine one or more pressure metrics associated with the second door control valve. In some embodiments, the motion controller 128 uses the one or more pressure metrics as feedback to regulate at least one of the inlet pressure associated with the second door control valve or the back pressure associated with the second door control valve.

In some embodiments, the third door assembly 406 comprises at least one of a third door (e.g., the door 130) or a third door control valve (e.g., the door control valve 102) coupled to the third door. In some embodiments, the third door is fitted to a third opening (not shown) to at least one of the vacuum transfer chamber defined by the vacuum transfer module 426 or the first wafer processing chamber defined by the first wafer processing station 428. In some embodiments, the door control apparatus 100 is configured to move the third door between a third door open position (e.g., the open position of the door 130 depicted in FIG. 2A) and a third door closed position (e.g., the closed position of the door 130 depicted in FIG. 2C). In some embodiments, when the third door is in the third door open position, the third door covers the third opening to inhibit access to at least one of the vacuum transfer chamber defined by the vacuum transfer module 426 or the first wafer processing chamber defined by the first wafer processing station 428. In some embodiments, when the third door is in the third door open position, the third door does not cover the third opening. In some embodiments, the door control apparatus 100 comprises at least one of (i) a seventh pressure control module (e.g., the first pressure control module 120) coupled to a third fluid inlet port (e.g., the fluid inlet port 110) defined by the third door control valve, or (ii) an eighth pressure control module (e.g., the second pressure control module 126) coupled to a third fluid outlet port (e.g., the fluid outlet port 108) defined by the third door control valve.

In some embodiments, the seventh pressure control module comprises at least one of the pressure regulator 124 or a seventh control valve (e.g., the first control valve 122). In some embodiments, the pressure regulator 124 is configured to supply fluid from the fluid supply 142 (or a different fluid supply) to the seventh control valve. In some embodiments, the pressure regulator 124 is configured to regulate a pressure of the supplied fluid to the seventh control valve. In some embodiments, the seventh pressure control module is configured to regulate an inlet pressure associated with the third door control valve. In some embodiments, the seventh pressure control module regulates the inlet pressure associated with the third door control valve by using the seventh control valve to control flow of the supplied fluid from the pressure regulator 124 to the third fluid inlet port. In some embodiments, the seventh control valve comprises at least one of a solenoid valve or other type of valve. In some embodiments, the seventh pressure control module regulates the inlet pressure associated with the third door control valve by using one or more of the techniques provided herein with respect to regulating the inlet pressure associated with the door control valve 102 using the first pressure control module 120.

In some embodiments, the eighth pressure control module comprises an eighth control valve. In some embodiments, the eighth control valve comprises at least one of a solenoid valve or other type of valve. In some embodiments, the eighth pressure control module is configured to regulate a back pressure associated with the third door control valve. In some embodiments, the eighth pressure control module regulates the back pressure associated with the third door control valve by using the eighth pressure control module (e.g., the eighth control valve) to control flow of fluid to or from the third door control valve. In some embodiments, the eighth pressure control module (and/or the motion controller 128 comprising the eighth pressure control module) is coupled to the fluid out channel 140 (e.g., air out channel). In some embodiments, the eighth pressure control module regulates the back pressure associated with the third door control valve by controlling flow of fluid between the third fluid outlet port and the fluid out channel 140. In some embodiments, the eighth pressure control module regulates the back pressure associated with the third door control valve by using one or more of the techniques provided herein with respect to regulating the back pressure associated with the door control valve 102 using the second pressure control module 126.

In some embodiments, the eighth pressure control module (and/or the motion controller 128 comprising the eighth pressure control module) is coupled to the second fluid supply. In some embodiments, the eighth pressure control module is configured to supply fluid from the second fluid supply to the door control valve 102. In some embodiments, the eighth pressure control module regulates the back pressure associated with the third door control valve by at least one of (i) controlling flow of fluid from the second fluid supply to the third fluid outlet port or (ii) controlling flow of fluid from the third fluid outlet port to the fluid out channel 140.

In some embodiments, the third door control valve comprises at least one of a third cylinder (e.g., the cylinder 112) or a third piston (e.g., the piston 114). In some embodiments, the third piston separates a seventh space in the third cylinder from an eighth space in the third cylinder. In some embodiments, the seventh pressure control module is coupled to the seventh space via the third fluid inlet port. In some embodiments, the inlet pressure associated with the third door control valve corresponds to a seventh pressure (e.g., air pressure) of the seventh space. In some embodiments, the eighth pressure control module is coupled to the eighth space via the third fluid outlet port. In some embodiments, the back pressure associated with the third door control valve corresponds to an eighth pressure (e.g., air pressure) of the eighth space.

In some embodiments, the door control apparatus 100 performs a fourth door open operation to move the third door of the third door assembly 406 from the third door closed position to the third door open position. In some embodiments, the door control apparatus 100 performs the fourth door open operation by at least one of (i) using the seventh pressure control module to adjust the inlet pressure associated with the third door control valve or (ii) using the eighth pressure control module to adjust the back pressure associated with the third door control valve. In some embodiments, the third door control valve of the third door assembly 406 comprises a third shaft (e.g., the shaft 116) coupled to the third piston and the third door. In some embodiments, at least one of the adjustment of the inlet pressure using the seventh pressure control module or the adjustment of the back pressure using the eighth pressure control module causes the third piston to move along a seventh predefined piston path. In some embodiments, the movement of the third piston along the seventh predefined piston path causes the third door of the third door assembly 406 to move along a seventh predefined door path from the third door closed position to the third door open position, such as due, at least in part, to the third door of the third door assembly 406 being coupled to the third piston via the third shaft.

In some embodiments, in response to performing the fourth door open operation to move the third door of the third door assembly 406 from the third door closed position to the third door open position, the third door is kept in the third door open position for a third time window to allow a third semiconductor wafer handling device (not shown) to transfer the first semiconductor wafer 432 from the vacuum transfer chamber defined by the vacuum transfer module 426 to the first wafer processing chamber defined by the first wafer processing station 428. In some embodiments, the third semiconductor wafer handling device comprises at least one of a robotic arm or other suitable device. In some embodiments, the third semiconductor wafer handling device supports (e.g., at least one of carries, grips, etc.) the first semiconductor wafer 432 and moves the first semiconductor wafer 432 through the third opening from the vacuum transfer chamber defined by the vacuum transfer module 426 to the first wafer processing chamber defined by the first wafer processing station 428 while the third door is in the third door open position.

In some embodiments, the door control apparatus 100 performs a fourth door close operation to move the third door of the third door assembly 406 from the third door open position to the third door closed position. In some embodiments, the door control apparatus 100 performs the fourth door close operation in response to transferring the first semiconductor wafer 432 through the third opening from the vacuum transfer chamber defined by the vacuum transfer module 426 to the first wafer processing chamber defined by the first wafer processing station 428. In some embodiments, the door control apparatus 100 performs the fourth door close operation by at least one of (i) using the seventh pressure control module to adjust the inlet pressure associated with the third door control valve or (ii) using the eighth pressure control module to adjust the back pressure associated with the third door control valve. In some embodiments, at least one of the adjustment of the inlet pressure using the seventh pressure control module or the adjustment of the back pressure using the eighth pressure control module causes the third piston to move along an eighth predefined piston path. In some embodiments, the movement of the third piston along the eighth predefined piston path causes the third door of the third door assembly 406 to move along an eighth predefined door path from the third door open position to the third door closed position, such as due, at least in part, to the third door of the third door assembly 406 being coupled to the third piston via the third shaft.

In some embodiments, the third door control valve comprises one, some, or all of the features, functions, interrelationships with other elements, etc. provided herein with respect to the door control valve 102. In some embodiments, the seventh pressure control module comprises one, some, or all of the features, functions, interrelationships with other elements, etc. provided herein with respect to the first pressure control module 120. In some embodiments, the eighth pressure control module comprises one, some, or all of the features, functions, interrelationships with other elements, etc. provided herein with respect to the second pressure control module 126. In some embodiments, the third door control valve, the seventh pressure control module, and/or the eighth pressure control module are used to perform the fourth door close operation on the third door of the third door assembly 406 using one or more of the techniques provided herein with respect to using the door control valve 102, the first pressure control module 120, and/or the second pressure control module 126 to perform the door close operation on the door 130. In some embodiments, at least one of the back pressure associated with the third door control valve or the inlet pressure associated with the third door control valve is controlled in accordance with the pressure data structure 300 of FIG. 3A to perform the fourth door close operation. In some embodiments, at least one of the back pressure associated with the third door control valve or the inlet pressure associated with the third door control valve is controlled based upon the pressure profile or a different pressure profile (stored on the motion controller 128, for example) to perform the fourth door close operation.

In some embodiments, the first wafer processing station 428 comprises at least one of (i) chemical vapor deposition (CVD) equipment, (ii) physical vapor deposition (PVD) equipment, (iii) etching equipment, such as at least one of plasma etching equipment, wet etching equipment, dry etching equipment, reactive-ion etching (RIE) equipment, atomic layer etching (ALE) equipment, buffered oxide etching equipment, or ion beam milling equipment, (iv) a furnace, such as a semiconductor furnace tool, (v) lithography equipment, (vi) chemical mechanical planarization (CMP) equipment, (vii) plating equipment, (viii) cleaning equipment, such as a cleaning tool comprising a cleaning tank in which a semiconductor wafer is at least one of washed, cleaned, etc., or (ix) other equipment.

In some embodiments, the first wafer processing station 428 performs a first semiconductor fabrication process on the first semiconductor wafer 432 while the first semiconductor wafer 432 is in the first wafer processing chamber. In some embodiments, the first semiconductor fabrication process comprises at least one of a CVD process, a PVD process, an etching process, a thermal process, a lithography process, a CMP process, a plating process, a cleaning process, or other process. In some embodiments, the first wafer processing station 428 performs the first semiconductor fabrication process in response to the door control apparatus 100 performing the fourth door close operation after transferring the first semiconductor wafer 432 through the third opening from the vacuum transfer chamber defined by the vacuum transfer module 426 to the first wafer processing chamber defined by the first wafer processing station 428.

In some embodiments, the door control apparatus 100 comprises a fourth set of sensors (e.g., a set of one or more sensors) associated with the third door control valve of the third door assembly 406. In some embodiments, the fourth set of sensors comprise one or more fluid flow sensors (e.g., flow meters) configured to determine one or more fluid flow metrics associated with the third door control valve. In some embodiments, the motion controller 128 uses the one or more fluid flow metrics as feedback to regulate at least one of the inlet pressure associated with the third door control valve or the back pressure associated with the third door control valve.

In some embodiments, the computer is configured to determine a fourth control valve health (e.g., a gate valve health) associated with the third door control valve based upon the one or more fluid flow metrics. In some embodiments, the third control valve health is indicative of at least one of (i) a fourth predicted lifespan associated with at least one of the third door control valve or the third cylinder or (ii) a fourth predicted replacement time associated with at least one of the third door control valve or the third cylinder. In some embodiments, the computer uses at least one of the fourth predicted lifespan or the fourth predicted replacement time to automatically schedule and trigger a maintenance operation associated with at least one of the third door control valve or the third cylinder. In some embodiments, the maintenance operation comprises allocating one or more resources (e.g., at least one of one or more tools, manpower, replacement items, etc.) to at least one of repair or replace at least one of the third door control valve or the third cylinder.

In some embodiments, the fourth set of sensors comprise one or more pressure sensors configured to determine one or more pressure metrics associated with the third door control valve. In some embodiments, the motion controller 128 uses the one or more pressure metrics as feedback to regulate at least one of the inlet pressure associated with the third door control valve or the back pressure associated with the third door control valve.

In some embodiments, the fourth door assembly 408 comprises at least one of a fourth door (e.g., the door 130) or a fourth door control valve (e.g., the door control valve 102) coupled to the fourth door. In some embodiments, the fourth door is fitted to a fourth opening (not shown) to at least one of the vacuum transfer chamber defined by the vacuum transfer module 426 or the second wafer processing chamber defined by the second wafer processing station 430. In some embodiments, the door control apparatus 100 is configured to move the fourth door between a fourth door open position (e.g., the open position of the door 130 depicted in FIG. 2A) and a fourth door closed position (e.g., the closed position of the door 130 depicted in FIG. 2C). In some embodiments, when the fourth door is in the fourth door open position, the fourth door covers the fourth opening to inhibit access to at least one of the vacuum transfer chamber defined by the vacuum transfer module 426 or the second wafer processing chamber defined by the second wafer processing station 430. In some embodiments, when the fourth door is in the fourth door open position, the fourth door does not cover the fourth opening. In some embodiments, the door control apparatus 100 comprises at least one of (i) a ninth pressure control module (e.g., the first pressure control module 120) coupled to a fourth fluid inlet port (e.g., the fluid inlet port 110) defined by the fourth door control valve, or (ii) a tenth pressure control module (e.g., the second pressure control module 126) coupled to a fourth fluid outlet port (e.g., the fluid outlet port 108) defined by the fourth door control valve.

In some embodiments, the ninth pressure control module comprises at least one of the pressure regulator 124 or a ninth control valve (e.g., the first control valve 122). In some embodiments, the pressure regulator 124 is configured to supply fluid from the fluid supply 142 (or a different fluid supply) to the ninth control valve. In some embodiments, the pressure regulator 124 is configured to regulate a pressure of the supplied fluid to the ninth control valve. In some embodiments, the ninth pressure control module is configured to regulate an inlet pressure associated with the fourth door control valve. In some embodiments, the ninth pressure control module regulates the inlet pressure associated with the fourth door control valve by using the ninth control valve to control flow of the supplied fluid from the pressure regulator 124 to the fourth fluid inlet port. In some embodiments, the ninth control valve comprises at least one of a solenoid valve or other type of valve. In some embodiments, the ninth pressure control module regulates the inlet pressure associated with the fourth door control valve by using one or more of the techniques provided herein with respect to regulating the inlet pressure associated with the door control valve 102 using the first pressure control module 120.

In some embodiments, the tenth pressure control module comprises a tenth control valve. In some embodiments, the tenth control valve comprises at least one of a solenoid valve or other type of valve. In some embodiments, the tenth pressure control module is configured to regulate a back pressure associated with the fourth door control valve. In some embodiments, the tenth pressure control module regulates the back pressure associated with the fourth door control valve by using the tenth pressure control module (e.g., the tenth control valve) to control flow of fluid to or from the fourth door control valve. In some embodiments, the tenth pressure control module (and/or the motion controller 128 comprising the tenth pressure control module) is coupled to the fluid out channel 140 (e.g., air out channel). In some embodiments, the tenth pressure control module regulates the back pressure associated with the fourth door control valve by controlling flow of fluid between the fourth fluid outlet port and the fluid out channel 140. In some embodiments, the tenth pressure control module regulates the back pressure associated with the fourth door control valve by using one or more of the techniques provided herein with respect to regulating the back pressure associated with the door control valve 102 using the second pressure control module 126.

In some embodiments, the tenth pressure control module (and/or the motion controller 128 comprising the tenth pressure control module) is coupled to the second fluid supply. In some embodiments, the tenth pressure control module is configured to supply fluid from the second fluid supply to the door control valve 102. In some embodiments, the tenth pressure control module regulates the back pressure associated with the fourth door control valve by at least one of (i) controlling flow of fluid from the second fluid supply to the fourth fluid outlet port or (ii) controlling flow of fluid from the fourth fluid outlet port to the fluid out channel 140.

In some embodiments, the fourth door control valve comprises at least one of a fourth cylinder (e.g., the cylinder 112) or a fourth piston (e.g., the piston 114). In some embodiments, the fourth piston separates a ninth space in the fourth cylinder from a tenth space in the fourth cylinder. In some embodiments, the ninth pressure control module is coupled to the ninth space via the fourth fluid inlet port. In some embodiments, the inlet pressure associated with the fourth door control valve corresponds to a ninth pressure (e.g., air pressure) of the ninth space. In some embodiments, the tenth pressure control module is coupled to the tenth space via the fourth fluid outlet port. In some embodiments, the back pressure associated with the fourth door control valve corresponds to a tenth pressure (e.g., air pressure) of the tenth space.

In some embodiments, the door control apparatus 100 performs a fifth door open operation to move the fourth door of the fourth door assembly 408 from the fourth door closed position to the fourth door open position. In some embodiments, the door control apparatus 100 performs the fifth door open operation by at least one of (i) using the ninth pressure control module to adjust the inlet pressure associated with the fourth door control valve or (ii) using the tenth pressure control module to adjust the back pressure associated with the fourth door control valve. In some embodiments, the fourth door control valve of the fourth door assembly 408 comprises a fourth shaft (e.g., the shaft 116) coupled to the fourth piston and the fourth door. In some embodiments, at least one of the adjustment of the inlet pressure using the ninth pressure control module or the adjustment of the back pressure using the tenth pressure control module causes the fourth piston to move along a ninth predefined piston path. In some embodiments, the movement of the fourth piston along the ninth predefined piston path causes the fourth door of the fourth door assembly 408 to move along a ninth predefined door path from the fourth door closed position to the fourth door open position, such as due, at least in part, to the fourth door of the fourth door assembly 408 being coupled to the fourth piston via the fourth shaft.

In some embodiments, in response to performing the fifth door open operation to move the fourth door of the fourth door assembly 408 from the fourth door closed position to the fourth door open position, the fourth door is kept in the fourth door open position for a fourth time window to allow a fourth semiconductor wafer handling device (not shown) to transfer the first semiconductor wafer 432 from the vacuum transfer chamber defined by the vacuum transfer module 426 to the second wafer processing chamber defined by the second wafer processing station 430. In some embodiments, the fourth semiconductor wafer handling device comprises at least one of a robotic arm or other suitable device. In some embodiments, the fourth semiconductor wafer handling device is the same as or different than the third semiconductor wafer handling device. In some embodiments, the fourth semiconductor wafer handling device supports (e.g., at least one of carries, grips, etc.) the first semiconductor wafer 432 and moves the first semiconductor wafer 432 through the fourth opening from the vacuum transfer chamber defined by the vacuum transfer module 426 to the second wafer processing chamber defined by the second wafer processing station 430 while the fourth door is in the fourth door open position.

In some embodiments, the door control apparatus 100 performs a fifth door close operation to move the fourth door of the fourth door assembly 408 from the fourth door open position to the fourth door closed position. In some embodiments, the door control apparatus 100 performs the fifth door close operation in response to transferring the first semiconductor wafer 432 through the fourth opening from the vacuum transfer chamber defined by the vacuum transfer module 426 to the second wafer processing chamber defined by the second wafer processing station 430. In some embodiments, the door control apparatus 100 performs the fifth door close operation by at least one of (i) using the ninth pressure control module to adjust the inlet pressure associated with the fourth door control valve or (ii) using the tenth pressure control module to adjust the back pressure associated with the fourth door control valve. In some embodiments, at least one of the adjustment of the inlet pressure using the ninth pressure control module or the adjustment of the back pressure using the tenth pressure control module causes the fourth piston to move along a tenth predefined piston path. In some embodiments, the movement of the fourth piston along the tenth predefined piston path causes the fourth door of the fourth door assembly 408 to move along a tenth predefined door path from the fourth door open position to the fourth door closed position, such as due, at least in part, to the fourth door of the fourth door assembly 408 being coupled to the fourth piston via the fourth shaft.

In some embodiments, the fourth door control valve comprises one, some, or all of the features, functions, interrelationships with other elements, etc. provided herein with respect to the door control valve 102. In some embodiments, the ninth pressure control module comprises one, some, or all of the features, functions, interrelationships with other elements, etc. provided herein with respect to the first pressure control module 120. In some embodiments, the tenth pressure control module comprises one, some, or all of the features, functions, interrelationships with other elements, etc. provided herein with respect to the second pressure control module 126. In some embodiments, the fourth door control valve, the ninth pressure control module, and/or the tenth pressure control module are used to perform the fifth door close operation on the fourth door of the fourth door assembly 408 using one or more of the techniques provided herein with respect to using the door control valve 102, the first pressure control module 120, and/or the second pressure control module 126 to perform the door close operation on the door 130. In some embodiments, at least one of the back pressure associated with the fourth door control valve or the inlet pressure associated with the fourth door control valve is controlled in accordance with the pressure data structure 300 of FIG. 3A to perform the fifth door close operation. In some embodiments, at least one of the back pressure associated with the fourth door control valve or the inlet pressure associated with the fourth door control valve is controlled based upon the pressure profile or a different pressure profile to perform the fifth door close operation.

In some embodiments, the second wafer processing station 430 comprises at least one of (i) CVD equipment, (ii) PVD equipment, (iii) etching equipment, such as at least one of plasma etching equipment, wet etching equipment, dry etching equipment, RIE equipment, ALE equipment, buffered oxide etching equipment, or ion beam milling equipment, (iv) a furnace, such as a semiconductor furnace tool, (v) lithography equipment, (vi) CMP equipment, (vii) plating equipment, (viii) cleaning equipment, such as a cleaning tool comprising a cleaning tank in which a semiconductor wafer is at least one of washed, cleaned, etc., or (ix) other equipment.

In some embodiments, the second wafer processing station 430 performs a second semiconductor fabrication process on the first semiconductor wafer 432 while the first semiconductor wafer 432 is in the second wafer processing chamber. In some embodiments, the second semiconductor fabrication process comprises at least one of a CVD process, a PVD process, an etching process, a thermal process, a lithography process, a CMP process, a plating process, a cleaning process, or other process. In some embodiments, the second wafer processing station 430 performs the second semiconductor fabrication process in response to the door control apparatus 100 performing the fifth door close operation after transferring the first semiconductor wafer 432 through the fourth opening from the vacuum transfer chamber defined by the vacuum transfer module 426 to the second wafer processing chamber defined by the second wafer processing station 430.

In some embodiments, the door control apparatus 100 comprises a fifth set of sensors (e.g., a set of one or more sensors) associated with the fourth door control valve of the fourth door assembly 408. In some embodiments, the fifth set of sensors comprise one or more fluid flow sensors (e.g., flow meters) configured to determine one or more fluid flow metrics associated with the fourth door control valve. In some embodiments, the motion controller 128 uses the one or more fluid flow metrics as feedback to regulate at least one of the inlet pressure associated with the fourth door control valve or the back pressure associated with the fourth door control valve.

In some embodiments, the computer is configured to determine a fifth control valve health (e.g., a gate valve health) associated with the fourth door control valve based upon the one or more fluid flow metrics. In some embodiments, the fourth control valve health is indicative of at least one of (i) a fifth predicted lifespan associated with at least one of the fourth door control valve or the fourth cylinder, or (ii) a fifth predicted replacement time associated with at least one of the fourth door control valve or the fourth cylinder. In some embodiments, the computer uses at least one of the fifth predicted lifespan or the fifth predicted replacement time to automatically schedule and trigger a maintenance operation associated with at least one of the fourth door control valve or the fourth cylinder. In some embodiments, the maintenance operation comprises allocating one or more resources (e.g., at least one of one or more tools, manpower, replacement items, etc.) to at least one of repair or replace at least one of the fourth door control valve or the fourth cylinder.

In some embodiments, the fifth set of sensors comprise one or more pressure sensors configured to determine one or more pressure metrics associated with the fourth door control valve. In some embodiments, the motion controller 128 uses the one or more pressure metrics as feedback to regulate at least one of the inlet pressure associated with the fourth door control valve or the back pressure associated with the fourth door control valve.

In some embodiments, one or more of the techniques of the present disclosure provide for improved uniformity of door close operations associated with different doors throughout the automated material handling system 400. In some embodiments, the improved uniformity is associated with at least one of (i) a reduced difference between operating speeds and/or accelerations of different door control valves performing door close operations, (ii) a reduced difference between operating speeds and/or accelerations of different doors, (iii) a reduced difference between valve closing forces associated with different door control valves performing door close operations, (iv) a reduced difference between door closing forces of different doors, (v) increased consistency of behavior of different door control valves and/or doors, (vi) a reduced difference between actuation times associated with different door control valves, etc. In some embodiments, the improved uniformity is due, at least in part, to controlling (based upon the pressure profile, for example) inlet pressures and back pressures associated with different control valves using the motion controller 128.

In some embodiments, the motion controller 128 comprises at least one of the third control valve, the fourth pressure control module (e.g., the fourth control valve), the fifth control valve, the sixth pressure control module (e.g., the sixth control valve), the seventh control valve, the eighth pressure control module (e.g., the eighth control valve), the ninth control valve, the tenth pressure control module (e.g., the tenth control valve), one, some or all sensors of the first set of sensors, one, some or all sensors of the second set of sensors, one, some or all sensors of the third set of sensors, one, some or all sensors of the fourth set of sensors, etc.

In some embodiments, the motion controller 128 (comprising the third control valve and the fourth control valve, for example) is coupled to the first door control valve of the first door assembly 402 via one or more first conduits 442. In some embodiments, the third control valve is coupled to the first fluid inlet port defined by the first door control valve via a first conduit of the one or more first conduits 442. In some embodiments, the fourth pressure control module (e.g., the fourth control valve) is coupled to the first fluid outlet port defined by the first door control valve via a second conduit of the one or more first conduits 442.

In some embodiments, the motion controller 128 (comprising the fifth control valve and the sixth control valve, for example) is coupled to the second door control valve of the second door assembly 404 via one or more second conduits 444. In some embodiments, the fifth control valve is coupled to the second fluid inlet port defined by the second door control valve via a first conduit of the one or more second conduits 444. In some embodiments, the sixth pressure control module (e.g., the sixth control valve) is coupled to the second fluid outlet port defined by the second door control valve via a second conduit of the one or more second conduits 444.

In some embodiments, the motion controller 128 (comprising the seventh control valve and the eighth control valve, for example) is coupled to the third door control valve of the third door assembly 406 via one or more third conduits 446. In some embodiments, the seventh control valve is coupled to the third fluid inlet port defined by the third door control valve via a first conduit of the one or more third conduits 446. In some embodiments, the eighth pressure control module (e.g., the eighth control valve) is coupled to the third fluid outlet port defined by the third door control valve via a second conduit of the one or more third conduits 446.

In some embodiments, the motion controller 128 (comprising the ninth control valve and the tenth control valve, for example) is coupled to the fourth door control valve of the fourth door assembly 408 via one or more fourth conduits 448. In some embodiments, the ninth control valve is coupled to the fourth fluid inlet port defined by the fourth door control valve via a first conduit of the one or more fourth conduits 448. In some embodiments, the tenth pressure control module (e.g., the tenth control valve) is coupled to the fourth fluid outlet port defined by the fourth door control valve via a second conduit of the one or more fourth conduits 448.

FIGS. 5A-5B illustrate a scenario 500 associated with the vacuum transfer module 426, in accordance with some embodiments. FIGS. 5A-5B illustrate perspective views from inside the vacuum transfer chamber (shown with reference number 554) defined by the vacuum transfer module 426, in accordance with some embodiments. FIG. 5A illustrates the third door (shown with reference number 530a) of the third door assembly 406 in the third door closed position and the fourth door (shown with reference number 530b) of the fourth door assembly 408 in the fourth door closed position, in accordance with some embodiments. In some embodiments, at least one of the third semiconductor wafer handling device or the fourth semiconductor wafer handling device comprises a robotic arm 552 configured to support (e.g., at least one of carry, grip, etc.) and/or move one or more semiconductor wafers, such as the first semiconductor wafer 432.

In some embodiments, the third door assembly 406 comprises at least one of the third door control valve (shown with reference number 502a) or a fifth door control valve 502b. In FIG. 5A, the third cylinder is shown with reference number 512a and the third shaft is shown with reference number 516a, in accordance with some embodiments. In some embodiments, the fifth door control valve 502b comprises at least one of a fifth cylinder 512b (e.g., the cylinder 112) or a fifth piston (not shown) (e.g., the piston 114). In some embodiments, the fifth piston separates an eleventh space in the fifth cylinder 512b from a twelfth space in the fifth cylinder 512b.

In some embodiments, the door control apparatus 100 comprises at least one of (i) an eleventh pressure control module (e.g., the first pressure control module 120) coupled to a fifth fluid inlet port (not shown) (e.g., the fluid inlet port 110) defined by the fifth door control valve 502b or (ii) a twelfth pressure control module (e.g., the second pressure control module 126) coupled to a fifth fluid outlet port (not shown) (e.g., the fluid outlet port 108) defined by the fifth door control valve 502b.

In some embodiments, the eleventh pressure control module comprises at least one of the pressure regulator 124 or an eleventh control valve (e.g., the first control valve 122). In some embodiments, the pressure regulator 124 is configured to supply fluid from the fluid supply 142 (or a different fluid supply) to the eleventh control valve. In some embodiments, the pressure regulator 124 is configured to regulate a pressure of the supplied fluid to the eleventh control valve. In some embodiments, the eleventh pressure control module is configured to regulate an inlet pressure associated with the fifth door control valve 502b. In some embodiments, the eleventh pressure control module regulates the inlet pressure associated with the fifth door control valve 502b by using the eleventh control valve to control flow of the supplied fluid from the pressure regulator 124 to the fifth fluid inlet port. In some embodiments, the eleventh control valve comprises at least one of a solenoid valve or other type of valve. In some embodiments, the eleventh pressure control module regulates the inlet pressure associated with the fifth door control valve 502b by using one or more of the techniques provided herein with respect to regulating the inlet pressure associated with the door control valve 102 using the first pressure control module 120. In some embodiments, the eleventh pressure control module is coupled to the eleventh space via the fifth fluid outlet port. In some embodiments, the inlet pressure associated with the fifth door control valve 502b corresponds to an eleventh pressure (e.g., air pressure) of the eleventh space.

In some embodiments, the twelfth pressure control module comprises a twelfth control valve. In some embodiments, the twelfth control valve comprises at least one of a solenoid valve or other type of valve. In some embodiments, the twelfth pressure control module is configured to regulate a back pressure associated with the fifth door control valve 502b. In some embodiments, the twelfth pressure control module regulates the back pressure associated with the fifth door control valve 502b by using the twelfth pressure control module (e.g., the twelfth control valve) to control flow of fluid to or from the fifth door control valve 502b. In some embodiments, the twelfth pressure control module (and/or the motion controller 128 comprising the twelfth pressure control module) is coupled to the fluid out channel 140 (e.g., air out channel). In some embodiments, the twelfth pressure control module regulates the back pressure associated with the fifth door control valve 502b by controlling flow of fluid between the fifth fluid outlet port and the fluid out channel 140. In some embodiments, the twelfth pressure control module regulates the back pressure associated with the fifth door control valve 502b by using one or more of the techniques provided herein with respect to regulating the back pressure associated with the door control valve 102 using the second pressure control module 126. In some embodiments, the twelfth pressure control module is coupled to the twelfth space via the fifth fluid outlet port. In some embodiments, the back pressure associated with the fifth door control valve 502b corresponds to a twelfth pressure (e.g., air pressure) of the twelfth space.

In some embodiments, the twelfth pressure control module (and/or the motion controller 128 comprising the twelfth pressure control module) is coupled to the second fluid supply. In some embodiments, the twelfth pressure control module is configured to supply fluid from the second fluid supply to the door control valve 102. In some embodiments, the twelfth pressure control module regulates the back pressure associated with the fifth door control valve 502b by at least one of (i) controlling flow of fluid from the second fluid supply to the fifth fluid outlet port or (ii) controlling flow of fluid from the fifth fluid outlet port to the fluid out channel 140.

In some embodiments, the door control apparatus 100 performs the fourth door open operation to move the third door 530a of the third door assembly 406 from the third door closed position (shown in FIG. 5A) to the third door open position (shown in FIG. 5B). In some embodiments, the door control apparatus 100 performs the fourth door open operation using the third door control valve 502a and the fifth door control valve 502b. In some embodiments, the door control apparatus 100 performs the fourth door open operation by at least one of (i) using the seventh pressure control module to adjust the inlet pressure associated with the third door control valve 502a, (ii) using the eighth pressure control module to adjust the back pressure associated with the third door control valve 502a, (iii) using the eleventh pressure control module to adjust the inlet pressure associated with the fifth door control valve 502b, or (iv) using the twelfth pressure control module to adjust the back pressure associated with the fifth door control valve 502b. In some embodiments, the fifth door control valve 502b of the third door assembly 406 comprises a fifth shaft 516b (e.g., the shaft 116) coupled to the fifth piston and the third door 530a. In some embodiments, at least one of the adjustment of the inlet pressure using the eleventh pressure control module or the adjustment of the back pressure using the twelfth pressure control module causes the fifth piston to move along an eleventh predefined piston path. In some embodiments, the fifth piston is moved along the eleventh predefined piston path concurrently with movement of the third piston along the seventh predefined piston path. In some embodiments, at least one of the movement of the fifth piston along the eleventh predefined piston path or the movement of the third piston along the seventh predefined piston path causes the third door 530a of the third door assembly 406 to move along the seventh predefined door path from the third door closed position to the third door open position, such as due, at least in part, to the third door 530a of the third door assembly 406 being coupled to at least one of the third piston via the third shaft 516a or the fifth piston via the fifth shaft 516b.

In some embodiments, the door control apparatus 100 performs the fourth door close operation to move the third door 530a of the third door assembly 406 from the third door open position (shown in FIG. 5B) to the third door closed position (shown in FIG. 5A). In some embodiments, the door control apparatus 100 performs the fourth door close operation using the third door control valve 502a and the fifth door control valve 502b. In some embodiments, the door control apparatus 100 performs the fourth door close operation by at least one of (i) using the seventh pressure control module to adjust the inlet pressure associated with the third door control valve 502a, (ii) using the eighth pressure control module to adjust the back pressure associated with the third door control valve 502a, (iii) using the eleventh pressure control module to adjust the inlet pressure associated with the fifth door control valve 502b, or (iv) using the twelfth pressure control module to adjust the back pressure associated with the fifth door control valve 502b. In some embodiments, at least one of the adjustment of the inlet pressure using the eleventh pressure control module or the adjustment of the back pressure using the twelfth pressure control module causes the fifth piston to move along a twelfth predefined piston path. In some embodiments, the fifth piston is moved along the twelfth predefined piston path concurrently with movement of the third piston along the eighth predefined piston path. In some embodiments, at least one of the movement of the fifth piston along the twelfth predefined piston path or the movement of the third piston along the eighth predefined piston path causes the third door 530a of the third door assembly 406 to move along the eighth predefined door path from the third door open position to the third door closed position, such as due, at least in part, to the third door 530a of the third door assembly 406 being coupled to at least one of the third piston via the third shaft 516a or the fifth piston via the fifth shaft 516b.

In some embodiments, the fourth door assembly 408 comprises at least one of the fourth door control valve (shown with reference number 502c) or a sixth door control valve 502d. In FIG. 5A, the fourth cylinder is shown with reference number 512c and the fourth shaft is shown with reference number 516c, in accordance with some embodiments. In some embodiments, the sixth door control valve 502d comprises at least one of a sixth cylinder 512d (e.g., the cylinder 112) or a sixth piston (not shown) (e.g., the piston 114). In some embodiments, the sixth piston separates a thirteenth space in the sixth cylinder 512d from a fourteenth space in the sixth cylinder 512d.

In some embodiments, the door control apparatus 100 comprises at least one of (i) a thirteenth pressure control module (e.g., the first pressure control module 120) coupled to a sixth fluid inlet port (not shown) (e.g., the fluid inlet port 110) defined by the sixth door control valve 502d or (ii) a fourteenth pressure control module (e.g., the second pressure control module 126) coupled to a sixth fluid outlet port (not shown) (e.g., the fluid outlet port 108) defined by the sixth door control valve 502d.

In some embodiments, the thirteenth pressure control module comprises at least one of the pressure regulator 124 or a thirteenth control valve (e.g., the first control valve 122). In some embodiments, the pressure regulator 124 is configured to supply fluid from the fluid supply 142 (or a different fluid supply) to the thirteenth control valve. In some embodiments, the pressure regulator 124 is configured to regulate a pressure of the supplied fluid to the thirteenth control valve. In some embodiments, the thirteenth pressure control module is configured to regulate an inlet pressure associated with the sixth door control valve 502d. In some embodiments, the thirteenth pressure control module regulates the inlet pressure associated with the sixth door control valve 502d by using the thirteenth control valve to control flow of the supplied fluid from the pressure regulator 124 to the sixth fluid inlet port. In some embodiments, the thirteenth control valve comprises at least one of a solenoid valve or other type of valve. In some embodiments, the thirteenth pressure control module regulates the inlet pressure associated with the sixth door control valve 502d by using one or more of the techniques provided herein with respect to regulating the inlet pressure associated with the door control valve 102 using the first pressure control module 120. In some embodiments, the thirteenth pressure control module is coupled to the thirteenth space via the sixth fluid outlet port. In some embodiments, the inlet pressure associated with the sixth door control valve 502d corresponds to a thirteenth pressure (e.g., air pressure) of the thirteenth space.

In some embodiments, the fourteenth pressure control module comprises a fourteenth control valve. In some embodiments, the fourteenth control valve comprises at least one of a solenoid valve or other type of valve. In some embodiments, the fourteenth pressure control module is configured to regulate a back pressure associated with the sixth door control valve 502d. In some embodiments, the fourteenth pressure control module regulates the back pressure associated with the sixth door control valve 502d by using the fourteenth pressure control module (e.g., the fourteenth control valve) to control flow of fluid to or from the sixth door control valve 502d. In some embodiments, the fourteenth pressure control module (and/or the motion controller 128 comprising the fourteenth pressure control module) is coupled to the fluid out channel 140 (e.g., air out channel). In some embodiments, the fourteenth pressure control module regulates the back pressure associated with the sixth door control valve 502d by controlling flow of fluid between the sixth fluid outlet port and the fluid out channel 140. In some embodiments, the fourteenth pressure control module regulates the back pressure associated with the sixth door control valve 502d by using one or more of the techniques provided herein with respect to regulating the back pressure associated with the door control valve 102 using the second pressure control module 126. In some embodiments, the fourteenth pressure control module is coupled to the fourteenth space via the sixth fluid outlet port. In some embodiments, the back pressure associated with the sixth door control valve 502d corresponds to a fourteenth pressure (e.g., air pressure) of the fourteenth space.

In some embodiments, the fourteenth pressure control module (and/or the motion controller 128 comprising the fourteenth pressure control module) is coupled to the second fluid supply. In some embodiments, the fourteenth pressure control module is configured to supply fluid from the second fluid supply to the door control valve 102. In some embodiments, the fourteenth pressure control module regulates the back pressure associated with the sixth door control valve 502d by at least one of (i) controlling flow of fluid from the second fluid supply to the sixth fluid outlet port, or (ii) controlling flow of fluid from the sixth fluid outlet port to the fluid out channel 140.

In some embodiments, the door control apparatus 100 performs the fourth door open operation to move the fourth door (shown with reference number 530b) of the fourth door assembly 408 from the fourth door closed position to the fourth door open position. In some embodiments, the door control apparatus 100 performs the fourth door open operation using the fourth door control valve 502c and the sixth door control valve 502d. In some embodiments, the door control apparatus 100 performs the fourth door open operation by at least one of (i) using the ninth pressure control module to adjust the inlet pressure associated with the fourth door control valve 502c, (ii) using the tenth pressure control module to adjust the back pressure associated with the fourth door control valve 502c, (iii) using the thirteenth pressure control module to adjust the inlet pressure associated with the sixth door control valve 502d, or (iv) using the fourteenth pressure control module to adjust the back pressure associated with the sixth door control valve 502d. In some embodiments, the sixth door control valve 502d of the fourth door assembly 408 comprises a sixth shaft 516d (e.g., the shaft 116) coupled to the sixth piston and the fourth door 530b. In some embodiments, at least one of the adjustment of the inlet pressure using the thirteenth pressure control module or the adjustment of the back pressure using the fourteenth pressure control module causes the sixth piston to move along a thirteenth predefined piston path. In some embodiments, the sixth piston is moved along the thirteenth predefined piston path concurrently with movement of the fourth piston along the ninth predefined piston path. In some embodiments, at least one of the movement of the sixth piston along the thirteenth predefined piston path or the movement of the fourth piston along the ninth predefined piston path causes the fourth door 530b of the fourth door assembly 408 to move along the ninth predefined door path from the fourth door closed position to the fourth door open position, such as due, at least in part, to the fourth door 530b of the fourth door assembly 408 being coupled to at least one of the fourth piston via the fourth shaft 516c or the sixth piston via the sixth shaft 516d.

In some embodiments, the door control apparatus 100 performs the fourth door close operation to move the fourth door 530b of the fourth door assembly 408 from the fourth door open position to the fourth door closed position. In some embodiments, the door control apparatus 100 performs the fourth door close operation using the fourth door control valve 502c and the sixth door control valve 502d. In some embodiments, the door control apparatus 100 performs the fourth door close operation by at least one of (i) using the ninth pressure control module to adjust the inlet pressure associated with the fourth door control valve 502c, (ii) using the tenth pressure control module to adjust the back pressure associated with the fourth door control valve 502c, (iii) using the thirteenth pressure control module to adjust the inlet pressure associated with the sixth door control valve 502d, or (iv) using the fourteenth pressure control module to adjust the back pressure associated with the sixth door control valve 502d. In some embodiments, at least one of the adjustment of the inlet pressure using the thirteenth pressure control module or the adjustment of the back pressure using the fourteenth pressure control module causes the sixth piston to move along a fourteenth predefined piston path. In some embodiments, the sixth piston is moved along the fourteenth predefined piston path concurrently with movement of the fourth piston along the tenth predefined piston path. In some embodiments, at least one of the movement of the sixth piston along the fourteenth predefined piston path or the movement of the fourth piston along the tenth predefined piston path causes the fourth door 530b of the fourth door assembly 408 to move along the tenth predefined door path from the fourth door open position to the fourth door closed position, such as due, at least in part, to the fourth door 530b of the fourth door assembly 408 being coupled to at least one of the fourth piston via the fourth shaft 516c or the sixth piston via the sixth shaft 516d.

FIG. 5B illustrates the third door 530a of the third door assembly 406 in the third door open position and the fourth door 530b of the fourth door assembly 408 in the fourth door closed position, in accordance with some embodiments. Thus, the third opening (shown with reference number 562) is not covered by the third door 530a of the third door assembly 406, in accordance with some embodiments. In some embodiments, the third opening 562 is defined by a wall 556. In some embodiments, the vacuum transfer chamber 554 is defined by at least one of the wall 556 or one or more other walls. In some embodiments, one or more semiconductor wafers are transferred through the third opening 562 from inside the vacuum transfer chamber 554 to a location (e.g., the first wafer processing chamber defined by the first wafer processing station 428) outside the vacuum transfer chamber 554. In some embodiments, one or more semiconductor wafers are transferred through the third opening 562 from a location (e.g., the first wafer processing chamber defined by the first wafer processing station 428) outside the vacuum transfer chamber 554 to inside the vacuum transfer chamber 554.

In some embodiments, the third door assembly 406 comprises a sealing component 564. In some embodiments, the sealing component 564 comprises at least one of an o-ring, a gasket, a rubber seal, or other suitable sealing component. In some embodiments, the sealing component 564 is affixed to and/or in contact with the wall 556 that defines the third opening 562. In some embodiments, the sealing component 564 is installed in a groove defined by the wall 556. Embodiments are contemplated in which the sealing component 564 is affixed to and/or in contact with the third door 530a. In some embodiments, the sealing component 564 is installed in a groove defined by the third door 530a.

In some embodiments, each conduit of one, some or all conduits of the present disclosure comprises at least one of one or more pipes, one or more tubes, one or more channels, etc. for conducting a fluid from a first component to a second component.

In some embodiments, each control valve of one, some or all control valves of the present disclosure comprises a pneumatic valve. Other valve types (other than pneumatic) of the control valves are within the scope of the present disclosure.

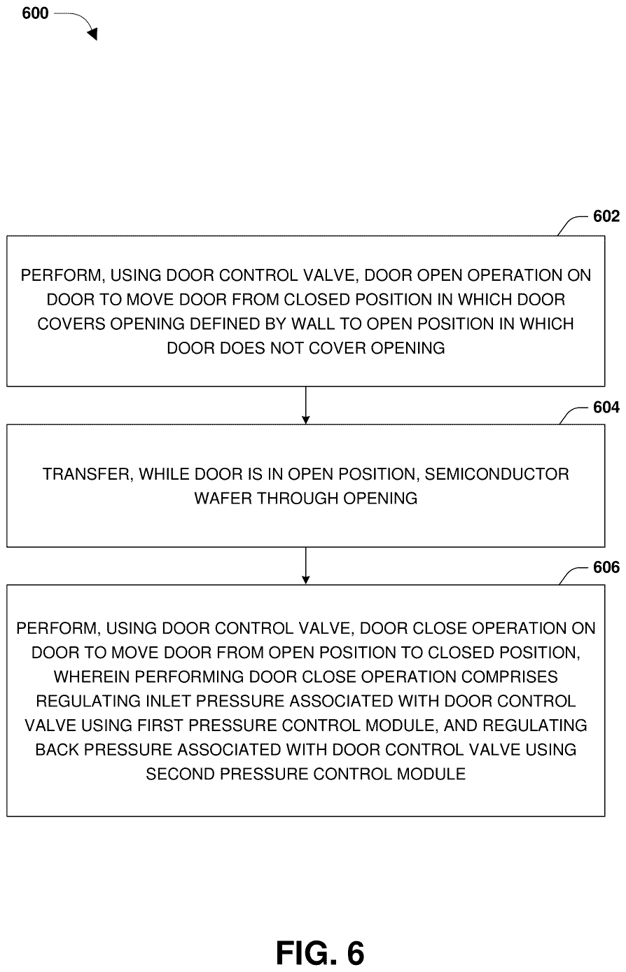

A method 600 of is illustrated in FIG. 6 in accordance with some embodiments. At 602, a door control valve (e.g., the door control valve 102) is used to perform a door open operation on a door (e.g., the door 130) to move the door from a closed position in which the door covers an opening (e.g., the opening 204) defined by a wall (e.g., the wall 202) to an open position in which the door does not cover the opening. At 604, a semiconductor wafer (e.g., the first semiconductor wafer 432) is transferred through the opening while the door is in the open position. At 606, the door control valve is used to perform a door close operation on the door to move the door from the open position to the closed position. The door close operation comprises regulating an inlet pressure associated with the door control valve using a first pressure control module (e.g., the first pressure control module 120) and regulating a back pressure associated with the door control valve using a second pressure control module (e.g., the second pressure control module 126).

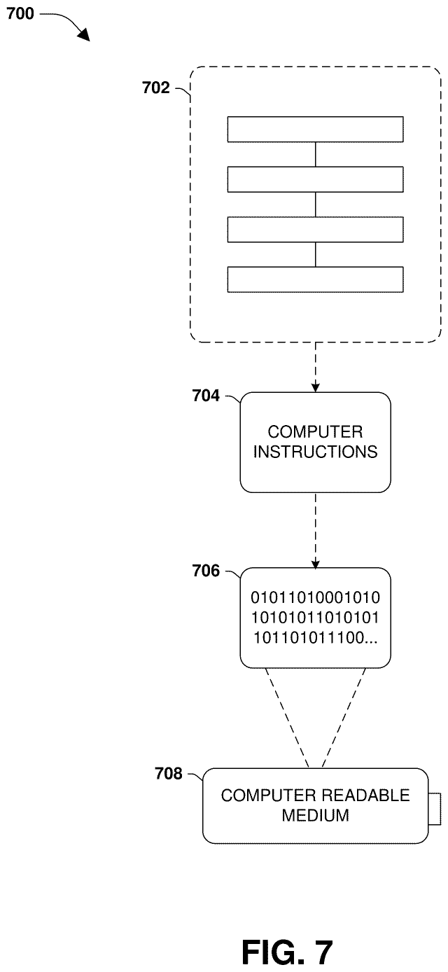

One or more embodiments involve a computer-readable medium comprising processor-executable instructions configured to implement one or more of the techniques presented herein. An exemplary computer-readable medium is illustrated in FIG. 7, wherein the embodiment 700 comprises a computer-readable medium 708 (e.g., a CD-R, DVD-R, flash drive, a platter of a hard disk drive, etc.), on which is encoded computer-readable data 706. This computer-readable data 706 in turn comprises a set of processor-executable computer instructions 704 configured to implement one or more of the principles set forth herein when executed by a processor. In some embodiments 700, the processor-executable computer instructions 704 are configured to implement a method 702, such as at least some of the aforementioned method(s) when executed by a processor. In some embodiments, the processor-executable computer instructions 704 are configured to implement a system, such as at least some of the one or more aforementioned systems when executed by a processor. In some embodiments, the processor-executable computer instructions 704 are configured to implement an apparatus, such as at least some of the one or more aforementioned apparatuses when executed by a processor. Many such computer-readable media may be devised by those of ordinary skill in the art that are configured to operate in accordance with the techniques presented herein.

In some embodiments, an automated material handling system is provided. The automated material handling system includes a wall defining an opening to a chamber. The automated material handling system includes a door fitted to the opening and configured to transition between a closed position in which the door covers the opening to inhibit access to the chamber and an open position in which the door does not cover the opening. The automated material handling system includes a semiconductor wafer handling device configured to transfer, while the door is in the open position, a semiconductor wafer at least one of to or from the chamber through the opening. The automated material handling system includes a door control apparatus. The door control apparatus includes a door control valve coupled to the door, a first pressure control module coupled to a fluid inlet port defined by the door control valve, and a second pressure control module coupled to a fluid outlet port defined by the door control valve. During a door close operation performed by the door control apparatus to move the door from the open position to the closed position, the door control apparatus is configured to regulate an inlet pressure associated with the door control valve using the first pressure control module, and regulate a back pressure associated with the door control valve using the second pressure control module.

In some embodiments, a method is provided. The method includes performing, using a door control valve, a door open operation on a door to move the door from a closed position in which the door covers an opening defined by a wall to an open position in which the door does not cover the opening. The method includes transferring, while the door is in the open position, a semiconductor wafer through the opening. The method includes performing, using the door control valve, a door close operation on the door to move the door from the open position to the closed position. Performing the door close operation includes regulating an inlet pressure associated with the door control valve using a first pressure control module, and regulating a back pressure associated with the door control valve using a second pressure control module.

In some embodiments, a door control apparatus is provided. The door control apparatus includes a door control valve coupled to a door fitted to an opening defined by a wall. The door is configured to transition between a closed position in which the door covers the opening and an open position in which the door does not cover the opening. The door control apparatus includes a first pressure control module coupled to a fluid inlet port defined by the door control valve. The door control apparatus includes a second pressure control module coupled to a fluid outlet port defined by the door control valve. During a door close operation to move the door from the open position to the closed position, the door control apparatus is configured to regulate an inlet pressure associated with the door control valve using the first pressure control module, and regulate a back pressure associated with the door control valve using the second pressure control module.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that Yeah illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An automated material handling system, comprising:
a wall defining an opening to a chamber;
a door fitted to the opening and configured to transition between a closed position in which the door covers the opening to inhibit access to the chamber and an open position in which the door does not cover the opening;
a semiconductor wafer handling device configured to transfer, while the door is in the open position, a semiconductor wafer at least one of to or from the chamber through the opening; and
a door control apparatus comprising:
a door control valve coupled to the door;
a first pressure control module coupled to a fluid inlet port defined by the door control valve; and
a second pressure control module coupled to a fluid outlet port defined by the door control valve,
wherein during a door close operation performed by the door control apparatus to move the door from the open position to the closed position, the door control apparatus is configured to:
regulate an inlet pressure associated with the door control valve using the first pressure control module; and
regulate a back pressure associated with the door control valve using the second pressure control module.

2. The automated material handling system of claim 1, comprising:
a sensor configured to determine one or more fluid flow metrics associated with the door control valve, wherein the second pressure control module regulates the back pressure associated with the door control valve based upon the one or more fluid flow metrics.

3. The automated material handling system of claim 1, comprising:
a wafer processing station configured to perform a semiconductor fabrication process on the semiconductor wafer, wherein the chamber is a wafer processing chamber defined by the wafer processing station.

4. The automated material handling system of claim 1, comprising:
a vacuum transfer module, wherein:
the chamber is a vacuum transfer chamber defined by the vacuum transfer module; and
the vacuum transfer module comprises a vacuum source configured to adjust a pressure in the vacuum transfer chamber.

5. The automated material handling system of claim 1, wherein:
the door control valve comprises a cylinder and a piston separating a first space in the cylinder from a second space in the cylinder;
the inlet pressure regulated by the first pressure control module corresponds to a first pressure of the first space; and
the back pressure regulated by the second pressure control module corresponds to a second pressure of the second space.

6. The automated material handling system of claim 5, wherein:
the door control valve comprises a shaft coupled to the piston and the door.

7. The automated material handling system of claim 1, wherein:
the door close operation comprises:
movement of the door in a first direction; and
movement of the door in a second direction different than the first direction.

8. The automated material handling system of claim 1, wherein:
during the door close operation, the door control apparatus is configured to increase the back pressure associated with the door control valve using the second pressure control module.

9. The automated material handling system of claim 1, wherein:
the first pressure control module comprises at least one of a pressure regulator or a solenoid valve.

10. The automated material handling system of claim 1, wherein:
the second pressure control module comprises a solenoid valve.

11. A method, comprising:
performing, using a door control valve, a door open operation on a door to move the door from a closed position in which the door covers an opening defined by a wall to an open position in which the door does not cover the opening;
transferring, while the door is in the open position, a semiconductor wafer through the opening; and
performing, using the door control valve, a door close operation on the door to move the door from the open position to the closed position, wherein performing the door close operation comprises:
regulating an inlet pressure associated with the door control valve using a first pressure control module; and
regulating a back pressure associated with the door control valve using a second pressure control module.

12. The method of claim 11, comprising:
determining, using a sensor, one or more fluid flow metrics associated with the door control valve, wherein regulating the back pressure associated with the door control valve using the second pressure control module is performed based upon the one or more fluid flow metrics.

13. The method of claim 11, wherein:
the door close operation comprises:
movement of the door in a first direction; and
movement of the door in a second direction different than the first direction.

14. The method of claim 11, wherein:
regulating the back pressure comprises increasing the back pressure.

15. The method of claim 11, wherein:
regulating the inlet pressure comprises increasing the inlet pressure.

16. A door control apparatus comprising:
a door control valve coupled to a door fitted to an opening defined by a wall, wherein the door is configured to transition between a closed position in which the door covers the opening and an open position in which the door does not cover the opening;
a first pressure control module coupled to a fluid inlet port defined by the door control valve; and
a second pressure control module coupled to a fluid outlet port defined by the door control valve,
wherein during a door close operation to move the door from the open position to the closed position, the door control apparatus is configured to:
regulate an inlet pressure associated with the door control valve using the first pressure control module; and
regulate a back pressure associated with the door control valve using the second pressure control module.

17. The door control apparatus of claim 16, wherein:
the door control valve comprises a cylinder and a piston separating a first space in the cylinder from a second space in the cylinder;
the inlet pressure regulated by the first pressure control module corresponds to a first pressure of the first space; and
the back pressure regulated by the second pressure control module corresponds to a second pressure of the second space.

18. The door control apparatus of claim 17, wherein:
the door control valve comprises a shaft coupled to the piston and the door.

19. The door control apparatus of claim 16, wherein:
the door close operation comprises:
movement of the door in a first direction; and
movement of the door in a second direction different than the first direction.

20. The door control apparatus of claim 16, wherein:
during the door close operation, the door control apparatus is configured to increase the back pressure associated with the door control valve using the second pressure control module.
